(19) United States
(12) Patent Application Publication
(10) Pub. No.: US 2023/0163035 A1
(43) Pub. Date: May 25, 2023

(54) SUBSTRATE FOR LIGHT EMITTING ELEMENTS, LIGHT EMITTING DEVICE INCLUDING SUBSTRATE FOR LIGHT EMITTING ELEMENTS, AND METHOD OF PRODUCING SUBSTRATE FOR LIGHT EMITTING ELEMENTS

(71) Applicant: NICHIA CORPORATION, Anan-shi (JP)

(72) Inventor: Kazuhiro KAMADA, Tokushima-shi (JP)

(73) Assignee: NICHIA CORPORATION, Anan-shi, Tokushima (JP)

(21) Appl. No.: 17/976,949

(22) Filed: Oct. 31, 2022

(30) Foreign Application Priority Data
Nov. 19, 2021 (JP) 2021-188538
Nov. 19, 2021 (JP) 2021188538

(51) Int. Cl. H01L 23/14; H01L 23/13; H01L 33/62; H01L 21/3213

(52) U.S. Cl. CPC H01L 23/142; H01L 23/13; H01L 33/62; H01L 21/32139

(57) ABSTRACT

A substrate for light emitting elements includes: a resin layer having a sheet shape, a first surface, and a second surface located opposite to the first surface. The second surface has one or more groove portions that includes a first groove portion. The second surface is divided by the first groove portion into a plurality of regions that include the first region and the second region. The resin layer includes a plurality of fiber bundles and a resin. The substrate includes a first electrically-conductive layer located in the first region of the resin layer; and a second electrically-conductive layer located in the second region of the resin layer. In a plan view, the at least one continuous fiber bundle extends inside the resin layer across the first region, a portion below the first groove portion, and the second region.

### CROSS REFERENCE TO RELATED APPLICATION

This application claims priority to Japanese Patent Application No. 2021-188538, filed on Nov. 19, 2021, the entire contents of which are hereby incorporated by reference.

### BACKGROUND

The present application relates to a substrate for light emitting elements, a light emitting device including a substrate for light emitting elements, and a method of producing a substrate for light emitting elements.

Light emitting devices that include light emitting elements, such as LED (Light Emitting Diode), mounted on a substrate have been known. In such light emitting devices, the substrate on which the light emitting elements are to be mounted (hereinafter, referred to as “substrate for light emitting elements”) includes, for example, a plurality of electrically-conductive layers on a surface opposite to the front surface of the substrate on which the light emitting elements are to be mounted such that the electrically-conductive layers can be electrically connected to the positive and negative electrodes of the light emitting elements. (See, for example, Japanese Patent Publication No. 2010-040801.)

### SUMMARY

As the distance between the plurality of electrically-conductive layers provided in the substrate for light emitting elements decreases, ion migration is more likely to occur between the electrically-conductive layers. Occurrence of ion migration can cause a short circuit between the electrically-conductive layers, which can cause the light emitting elements to erroneously operate or fail to emit light.

An object of the present disclosure is to provide a substrate for light emitting elements in which a short circuit due to ion migration between electrically-conductive layers is suppressed, a light emitting device including such a substrate for light emitting elements, and a method of producing such a substrate for light emitting elements.

According to one aspect of the present disclosure, a substrate for light emitting elements includes: a resin layer, a first electrically-conductive layer, a second electrically-conductive layer. The resin layer has a sheet shape, a first surface, and a second surface located opposite to the first surface. The second surface has one or more groove portions. The second surface is divided by the first groove portion into a plurality of regions that include the first region and the second region. The resin layer includes a plurality of fiber bundles and a resin. The first electrically-conductive layer is located in the first region of the resin layer. The second electrically-conductive layer is located in the second region of the resin layer. In a cross-sectional view including the first electrically-conductive layer, the first groove portion, and the second electrically-conductive layer, at least one continuous fiber bundle included in the plurality of fiber bundles includes a portion that is located at a position shallower than a bottom of the first groove portion. In a plan view, the at least one continuous fiber bundle extends inside the resin layer across the first region, a portion below the first groove portion, and the second region in a plan view.

According to another aspect of the present disclosure, a light emitting device includes: the substrate as set forth in the foregoing paragraph, the first electrically-conductive layer being a first lower electrically-conductive layer, the second electrically-conductive layer being a second lower electrically-conductive layer, the substrate further including a first upper electrically-conductive layer and a second upper electrically-conductive layer on the first surface side of the resin layer, the first upper electrically-conductive layer and the second upper electrically-conductive layer being spaced away from each other, and the first upper electrically-conductive layer being electrically connected to the first lower electrically-conductive layer, and the second upper electrically-conductive layer being electrically connected to the second lower electrically-conductive layer; and at least one light emitting element provided on the first surface side of the resin layer, wherein the at least one light emitting element includes a first light emitting element, the first light emitting element including a first electrode electrically connected to the first upper electrically-conductive layer and a second electrode electrically connected to the second upper electrically-conductive layer.

According to still another aspect of the present disclosure, a method of producing a substrate for light emitting elements, includes: providing a sheet-like metal plate and a pre-preg, the metal plate having a first surface and one or more raised portions at the first surface, the pre-preg including a plurality of fiber bundles and a resin; binding together the first surface of the metal plate and the pre-preg; forming a resin layer that includes curing the pre-preg; forming a resist on the metal plate; etching away the one or more raised portions of the metal plate; and removing the resist. The etching includes dividing the metal plate by the one or more groove portions into two or more parts that includes a first region and a second region.

According to certain embodiments of the present disclosure, a substrate for light emitting elements in which a short circuit due to ion migration between electrically-conductive layers is suppressed, a light emitting device including such a substrate for light emitting elements, and a method of producing such a substrate for light emitting elements can be provided.

### BRIEF DESCRIPTION OF THE DRAWINGS

FIG. 1A is a schematic top view of a substrate for light emitting elements according to an embodiment of the present disclosure.

FIG. 1B is a schematic bottom view of the substrate shown in FIG. 1A.

FIG. 1C is a schematic cross-sectional view of the substrate taken along line 1C-1C shown in FIG. 1A and FIG. 1B.

FIG. 1D is an enlarged schematic cross-sectional view showing a part of FIG. 1C.

FIG. 2A is a schematic top view of a light emitting device according to an embodiment of the present disclosure.

FIG. 2B is a schematic cross-sectional view of the light emitting device taken along line 2B-2B shown in FIG. 2A.

FIG. 3A is an enlarged schematic cross-sectional view showing a part of a resin layer according to an embodiment.

FIG. 3B is an enlarged schematic top view showing an example of a fiber layer.

FIG. 3C is an enlarged schematic bottom view showing a part of the substrate for light emitting elements for illustrating the arrangement of the first fiber bundle.

FIG. 4A is a schematic bottom view showing a first substrate according to an embodiment.

FIG. 4B is an enlarged schematic bottom view showing a part of the first substrate shown in FIG. 4A.

FIG. 4C is a schematic cross-sectional view of the first substrate taken along line 4C-4C shown in FIG. 4B.

FIG. 5 is an enlarged schematic bottom view showing a part of an alternative first substrate according to an embodiment.

FIG. 6 is a cross-sectional view showing another example of a light source section.

FIG. 7A is a schematic top view showing a light emitting device according to an embodiment.

FIG. 7B is a schematic bottom view of the light emitting device shown in FIG. 7A.

FIG. 7C is a schematic cross-sectional view of the light emitting device taken along line 7C-7C shown in FIG. 7A and FIG. 7B.

FIG. 7D is a schematic lateral side view of the light emitting device shown in FIG. 7A.

FIG. 8A is an enlarged schematic top view showing a part of a metal plate for use in production of the substrate for light emitting elements according to an embodiment.

FIG. 8B is a schematic cross-sectional view of the metal plate taken along line 8B-8B shown in FIG. 8A.

FIG. 8C is an enlarged schematic cross-sectional view showing a part of a pre-preg for use in production of the substrate for light emitting elements according to an embodiment.

FIG. 9A is a cross-sectional view showing a production step of the substrate for light emitting elements according to an embodiment.

FIG. 9B is a cross-sectional view showing a production step of the substrate for light emitting elements according to an embodiment.

FIG. 9C is a cross-sectional view showing a production step of the substrate for light emitting elements according to an embodiment.

FIG. 9D is a cross-sectional view showing a production step of the substrate for light emitting elements according to an embodiment.

FIG. 9E is a cross-sectional view showing a production step of the substrate for light emitting elements according to an embodiment.

FIG. 9F is a cross-sectional view showing a production step of the substrate for light emitting elements according to an embodiment.

FIG. 9G is a cross-sectional view showing a production step of the substrate for light emitting elements according to an embodiment.

FIG. 10A is a schematic top view of a substrate for light emitting elements according to Variant Example 1.

FIG. 10B is a schematic bottom view of the substrate shown in FIG. 10A.

FIG. 10C is a schematic cross-sectional view of the substrate taken along line 10C-10C shown in FIG. 10A and FIG. 10B.

FIG. 11 is an enlarged schematic bottom view showing a part of the first substrate of Variant Example 1.

FIG. 12A is a schematic top view showing a light emitting device of Variant Example 1.

FIG. 12B is a schematic bottom view of the light emitting device shown in FIG. 12A.

FIG. 12C is a schematic cross-sectional view of the light emitting device taken along line 12C-12C shown in FIG. 12A and FIG. 12B.

FIG. 13 is a cross-sectional view of a structure equivalent to the light emitting device shown in FIG. 12C from which a lens has been removed.

FIG. 14A is a schematic top view of a substrate for light emitting elements according to Variant Example 2.

FIG. 14B is a schematic bottom view of the substrate shown in FIG. 14A.

FIG. 14C is a schematic cross-sectional view of the substrate taken along line 14C-14C shown in FIG. 14A and FIG. 14B.

FIG. 15 is an enlarged schematic bottom view showing a part of the first substrate of Variant Example 2.

FIG. 16 is a schematic bottom view showing an alternative substrate for light emitting elements according to Variant Example 2.

FIG. 17A is a schematic bottom view of a substrate for light emitting elements according to Variant Example 3.

FIG. 17B is a schematic bottom view of an alternative substrate for light emitting elements according to Variant Example 3.

FIG. 18 is a schematic bottom view of a still alternative substrate for light emitting elements according to Variant Example 3.

FIG. 19A is a schematic cross-sectional view of a substrate for light emitting elements according to Variant Example 4.

FIG. 19B is a schematic cross-sectional view of an alternative substrate for light emitting elements according to Variant Example 4.

FIG. 19C is a schematic cross-sectional view of an alternative substrate for light emitting elements according to Variant Example 4.

FIG. 20 is a schematic bottom view of an alternative substrate for light emitting elements according to Variant Example 4.

FIG. 21 is an enlarged schematic cross-sectional view illustrating a reference example processing method of forming a groove portion in a resin layer.

### DETAILED DESCRIPTION

Hereinafter, embodiments of the present invention are described with appropriate reference to the drawings. A substrate for light emitting elements and a light emitting device that will be described below are provided as examples for giving a concrete form to the technical concepts of the present invention. However, the present invention is not limited to the description below unless specified otherwise. The description provided for one embodiment is also applicable to other embodiments and variations. The sizes, relative positions, etc., of members shown in the drawings are sometimes exaggerated for clear description.

In the following description, components of like functions may be denoted by like reference signs and may not be described redundantly. Sometimes, components that are not referred to in the description may not be accompanied with reference characters. Terms indicating specific directions and positions (e.g., “upper,” “lower,” “right,” “left,” and other terms including or related such terms) may be used in the following description. Note however that these terms are used merely for the ease of understanding relative directions or positions in the figure being referred to. The arrangement of components in figures from documents other than the present disclosure, actual products, actual manufacturing apparatuses, etc., does not need to be equal to that shown in the figure being referred to, as long as it conforms with the directional or positional relationship as indicated by terms such as “upper” and “lower” in the figure being referred to. In the present disclosure, the term “parallel” encompasses cases where two straight lines, sides, planes, etc., are in the range of about 0±5°, unless otherwise specified. In the present disclosure, the terms “perpendicular” and “orthogonal” encompass cases where two straight lines, sides, planes, etc., are in the range of about 90±5°, unless otherwise specified.

The drawings described below also show arrows representative of the X, Y and Z axes that are perpendicular to one another. The forward direction of the arrow in the x direction is denoted as +x direction, and the direction opposite to the +x direction is denoted as −x direction. The forward direction of the arrow in the y direction is denoted as +y direction, and the direction opposite to the +y direction is denoted as −y direction. The forward direction of the arrow in the z direction is denoted as +z direction, and the direction opposite to the +z direction is denoted as −z direction. In the embodiments, according to an example, light emitting elements are to emit light to the +z direction side. Note that, however, this does not limit the orientation of a light emitting device or light emitting element when used. The orientation of the light emitting device or light emitting element is discretionary. In the claims and the specification, the phrase “plan view” or “viewed in plan” means viewing an object from the +z direction or the −z direction, and the term “planar shape” means the shape of an object as viewed in the z direction.

In the present specification and claims, when there are a plurality of items of a certain component and these items are described as being distinct from one another, these items may be preceded by ordinal numerals (e.g., first, second) for distinction. Between the present specification and the claims, objects to be distinguished may be different. Thus, if a component recited in a claim is preceded by the same ordinal numeral as that of a component described in the specification, an object specified by the component recited in the claim may not be identical with an object specified by the component described in the specification.

For example, consider that there are three items of a component in the present specification, which are distinguished by ordinal numerals, “first,” “second” and “third.” When the “first” and “third” items of the component in the specification are recited in the claims, they may be referred to as the “first” and “second” items in the claims for the sake of readability. In this case, the items of the component preceded by “first” and “second” in the claims correspond to the “first” and “third” items of the component in the specification. Note that this rule applies not only to components but also rationally and flexibly to other objects.

### Embodiments

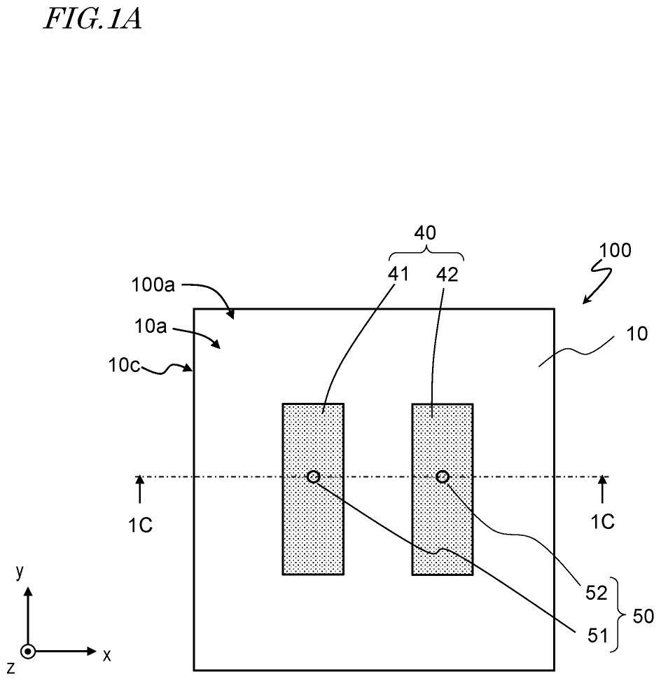

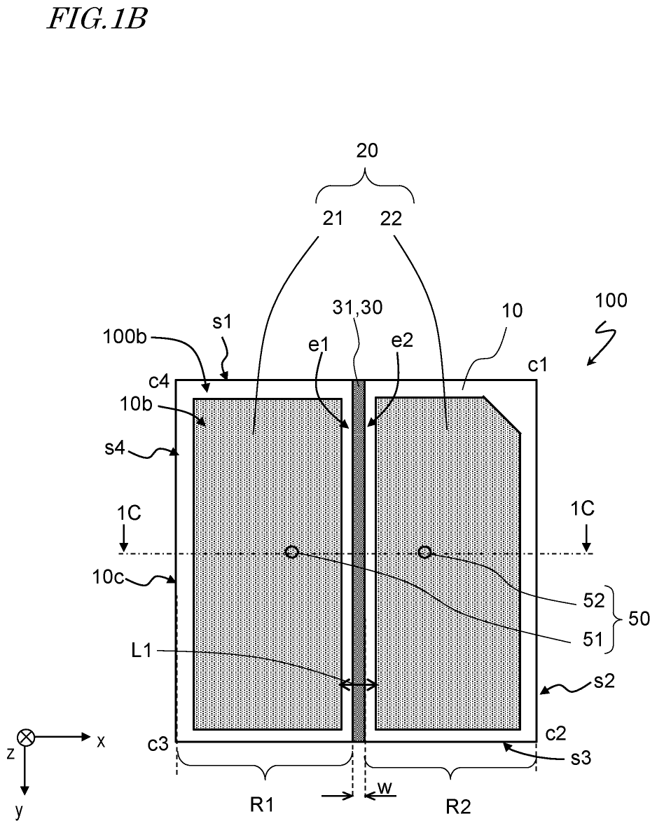

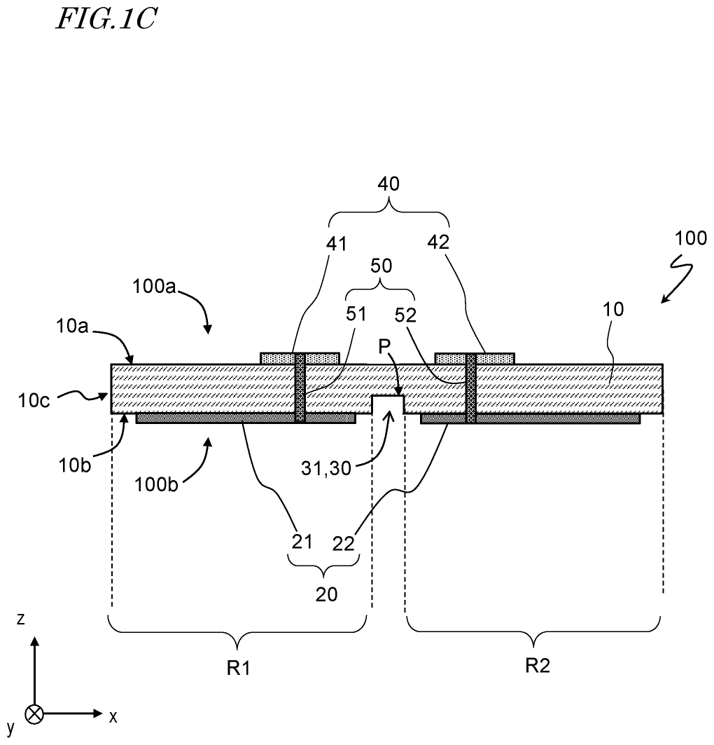

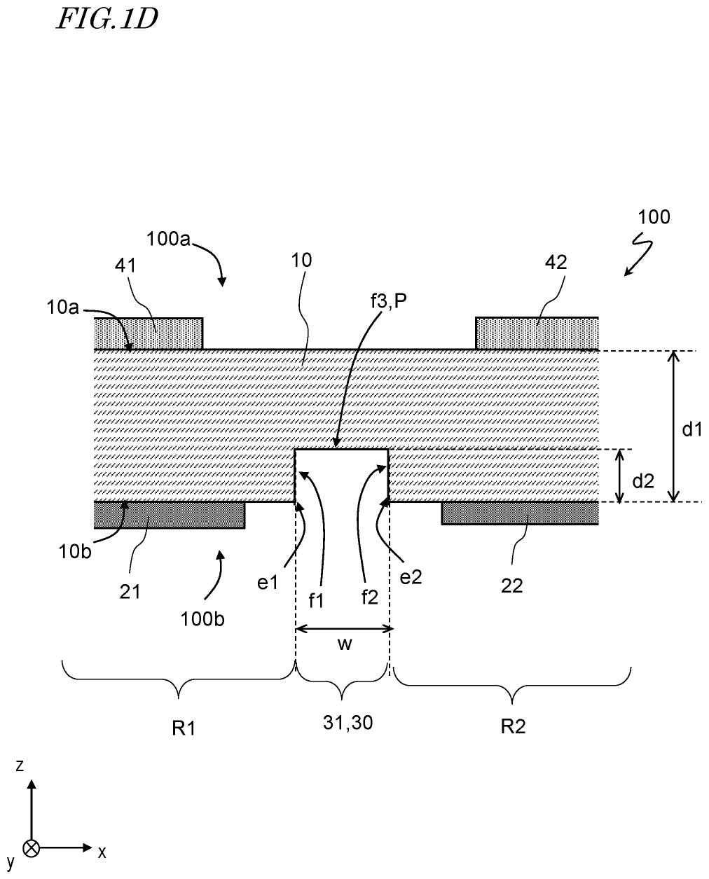

FIG. 1A, FIG. 1B, FIG. 1C and FIG. 1D are diagrams showing a substrate 100 for light emitting elements (hereinafter, sometimes simply referred to as “substrate”) according to an embodiment of the present disclosure. FIG. 1A is a schematic top view of the substrate 100. FIG. 1B is a schematic bottom view of the substrate 100. FIG. 1C is a schematic cross-sectional view of the substrate 100 taken along line 1C-1C shown in FIG. 1A and FIG. 1B. FIG. 1D is an enlarged cross-sectional view showing a part of FIG. 1C.

The substrate 100 includes a sheet-like resin layer 10, and a plurality of electrically-conductive layers 20 that include a first electrically-conductive layer 21 and a second electrically-conductive layer 22. The resin layer 10 has a first surface 10a and a second surface 10b located opposite to the first surface 10a. The second surface 10b has at least one groove portion 30, which includes the first groove portion 31, and a first region R1 and a second region R2 such that the first groove portion 31 is interposed therebetween. The resin layer 10 at least includes a plurality of fiber bundles and a resin. In the resin layer 10, at least one continuous first fiber bundle included in the plurality of fiber bundles that is located at a position shallower than the bottom P of the first groove portion 31 in a cross-sectional view including the first electrically-conductive layer 21, the first groove portion 31 and the second electrically-conductive layer 22 is provided so as to extend across the first region R1, the first groove portion 31 and the second region R2 in a plan view.

The substrate 100 has the upper surface 100a and the lower surface 100b located opposite to the upper surface 100a. The first surface 10a of the resin layer 10 is located on the same side as the upper surface 100a of the substrate 100. The second surface 10b is located on the same side as the lower surface 100b of the substrate 100.

The plurality of electrically-conductive layers 20, which includes the first electrically-conductive layer 21 and the second electrically-conductive layer 22, are provided on the second surface 10b of the resin layer 10. The first electrically-conductive layer 21 is located in the first region R1 of the resin layer 10. The second electrically-conductive layer 22 is located in the second region R2 of the resin layer 10. In the present specification, an electrically-conductive layer 20 provided on the second surface 10b of the resin layer 10 may be referred to as “lower electrically-conductive layer.”

In the substrate 100 of the present embodiment, the first groove portion 31 is provided in the second surface 10b of the resin layer 10, so that the distance measured along the second surface 10b of the resin layer 10 between the first electrically-conductive layer 21 and the second electrically-conductive layer 22 (hereinafter, sometimes referred to as “creepage distance of insulation”) can be large. Thus, occurrence of a short circuit due to ion migration between the first electrically-conductive layer 21 and the second electrically-conductive layer 22 can be suppressed.

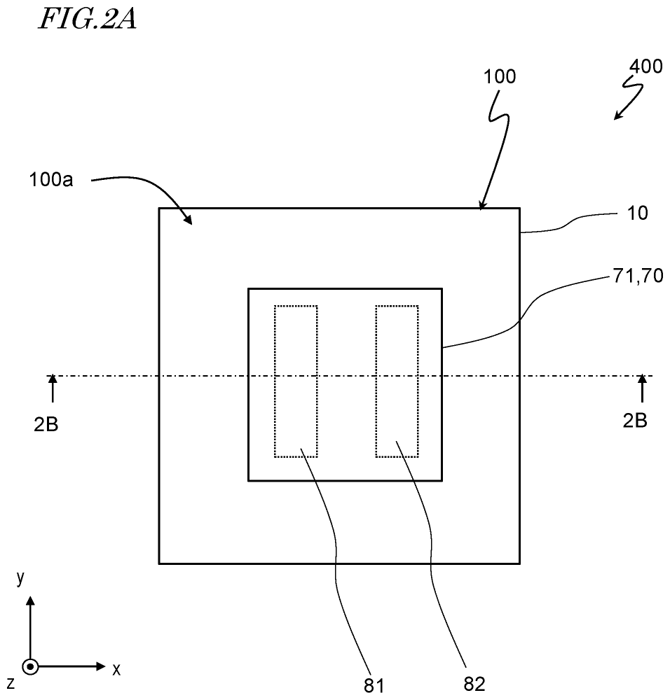

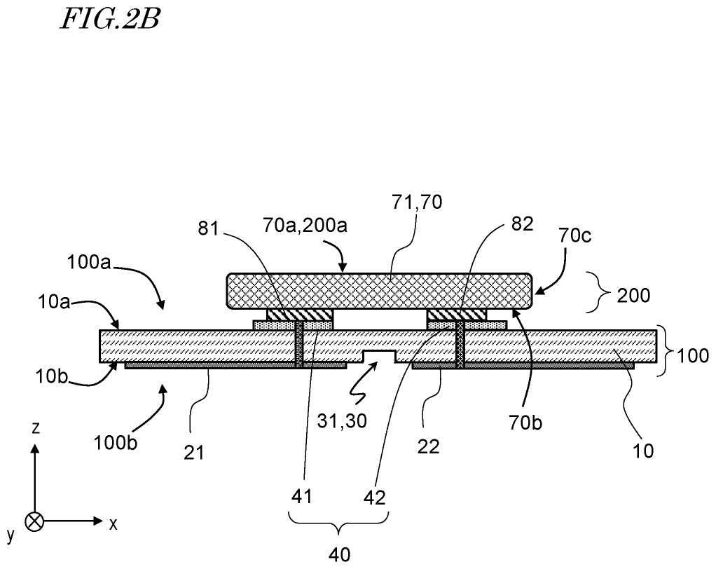

FIG. 2A is a schematic top view of a light emitting device according to an embodiment of the present disclosure. FIG. 2B is a schematic cross-sectional view of the light emitting device taken along line 2B-2B shown in FIG. 2A.

A light emitting device 400 of the present embodiment includes a substrate 100 for light emitting elements and at least one light emitting element 70. The substrate 100 for light emitting elements includes a first lower electrically-conductive layer 21, a second lower electrically-conductive layer 22, and a first upper electrically-conductive layer 41 and a second upper electrically-conductive layer 42 provided on the first surface 10a side of the resin layer 10, such that the upper electrically-conductive layers 41 and 42 are spaced away from each other. Herein, the first electrically-conductive layer 21 shown in FIG. 1B and FIG. 1C is the first lower electrically-conductive layer 21, and the second electrically-conductive layer 22 shown in FIG. 1B and FIG. 1C is the second lower electrically-conductive layer 22. The first upper electrically-conductive layer 41 is electrically connected to the first lower electrically-conductive layer 21. The second upper electrically-conductive layer 42 is electrically connected to the second lower electrically-conductive layer 22. The light emitting device 400 of the present embodiment includes the substrate 100 for light emitting elements and at least one light emitting element 70 provided on the first surface 10a side of the resin layer 10. The at least one light emitting element 70 includes a first light emitting element 71. The first light emitting element 71 includes a first electrode 81 electrically connected to the first upper electrically-conductive layer 41 and a second electrode 82 electrically connected to the second upper electrically-conductive layer 42.

Hereinafter, respective components will be described in detail.

[Resin Layer 10]

The resin layer 10 at least includes a plurality of fiber bundles 11 and a resin 12 as will be described later. In the configuration illustrated in FIG. 1A, FIG. 1B and FIG. 1C, the resin layer 10 is in the form of a sheet. The resin layer 10 has the first surface 10a and the second surface 10b, which are parallel to the xy plane, and lateral surfaces 10c extending between the first surface 10a and the second surface 10b. The lateral surfaces 10c may be perpendicular to the xy plane. The thickness d1 of the resin layer 10 is, for example, equal to or greater than 200 μm and equal to or smaller than 900 μm. Herein, the thickness d1 of the resin layer 10 is, for example, 300 μm. The “thickness of the resin layer” refers to the distance in the z direction between the first surface 10a and a part of the second surface 10b of the resin layer 10 in which the groove portion 30 is not provided.

The planar shape of the resin layer 10, i.e., the shape of the first surface 10a and the second surface 10b, is for example tetragonal. Each side of the tetragonal shape is parallel to the x axis or the y axis. In the example shown in FIG. 1B, the second surface 10b has a rectangular shape that has four corners c1, c2, c3 and c4 and four sides s1, s2, s3 and s4. The sides s1 and s3 are parallel to the x axis, and the side s3 is located on the +y side of the side s1. The sides s2 and s4 are parallel to the y axis, and the side s4 is located on the −x side of the side s2. The corner formed by the side s1 and the side s2 is the corner c1. The corner c2 is formed by the side s2 and the side s3. The corner c3 is formed by the side s3 and the side s4. The corner c4 is formed by the side s4 and the side s1. The first surface 10a shown in FIG. 1A also has a rectangular shape that is substantially equal to the second surface 10b. The size of the first surface 10a and the second surface 10b is, for example, 6 mm×6 mm. The planar shape of the resin layer 10 may be a polygonal shape other than tetragonal shapes, for example, a triangular, pentagonal, or hexagonal shape. Note that, in this specification, the polygonal shape may involve a polygon with reshaped corners subjected to processing, such as cutting angles, chamfering, beveling, rounding, or the like, will be referred to as a polygon. Moreover, the location of such processing is not limit to a corner (an end of a side). Rather, a shape subjected to processing in the intermediate portion of a side will similarly be referred to as a polygon. In other words, any polygon-based shape subjected to processing should be understood to be included in the interpretation of a “polygon” in the description and the accompanying claims. Alternatively, the planar shape of the resin layer 10 may be a shape that includes a curve of a circular or elliptical shape.

As shown in FIG. 1B, the second surface 10b of the resin layer 10 has at least one groove portion 30 and a plurality of planned electrically-conductive layer regions. The planned electrically-conductive layer regions mean regions on which electrically-conductive layers 20 are to be provided. The groove portion 30 is located between two adjacent planned electrically-conductive layer regions. In the present embodiment, the plurality of planned electrically-conductive layer regions include a first region R1 and a second region R2. The groove portion 30 includes a first groove portion 31 located between the first region R1 and the second region R2.

In the example shown in FIG. 1B, the second surface 10b includes the first groove portion 31, the first region R1 located on the −x side of the first groove portion 31, and the second region R2 located on the +x side of the first groove portion 31. The first groove portion 31 is a groove portion extending linearly in the y axis direction between the first region R1 and the second region R2. The first region R1 refers to a region surrounded by the first groove portion 31 and the periphery of the second surface 10b (herein, the sides s3, s4 and s1), and the second region R2 refers to a region surrounded by the first groove portion 31 and the periphery of the second surface 10b (herein, the sides s1, s2 and s3). In this example, the opposite ends of the first groove portion 31 are in contact with the sides s1 and s3, respectively, of the second surface 10b although there may be a gap between the first groove portion 31 and the side s1 or between the first groove portion 31 and the side s3. Note that the first groove portion 31 may be provided according to the planar shape and the positional relationship of the first region R1 and the second region R2 such that, for example, the first groove portion 31 extends parallel to the x axis or extends in a direction intersecting with the x axis or the y axis (e.g., a direction inclined by ±450 with respect to the x axis). When the resin layer 10 has a polygonal planar shape, such as tetragonal planar shape, the first groove portion 31 may be provided between two vertices of the polygon so as to extend along the diagonal joining these two vertices.

The first groove portion 31 is preferably provided so as to intersect with a line segment of shortest distance L1 between the first electrically-conductive layer 21 and the second electrically-conductive layer 22 in a plan view. With this arrangement, occurrence of a short circuit due to ion migration between the first electrically-conductive layer 21 and the second electrically-conductive layer 22 can be more effectively suppressed.

The second surface 10b of the resin layer 10 may be divided (separated) by at least one groove portion 30 into a plurality of regions that include the first region R1 and the second region R2. The phrase “divided by a groove portion” or “separated by a groove portion” means that the groove portion 30 is provided such that the second surface 10b is divided into a plurality of regions and the groove portion 30 defines at least part of the periphery of each of the regions. The groove portion 30 may not be provided such that the planned electrically-conductive layer regions are thoroughly spaced away from each other. For example, the space between two planned electrically-conductive layer regions may include a portion in which the groove portion 30 is not provided.

The number of groove portions 30 and the number of planned electrically-conductive layer regions are not particularly limited. The second surface 10b of the resin layer 10 may have a plurality of groove portions 30 and three or more planned electrically-conductive layer regions. For example, the second surface 10b may be divided by a plurality of groove portions 30 into three or more planned electrically-conductive layer regions. The plurality of planned electrically-conductive layer regions divided by the groove portions 30 are each provided with a single electrically-conductive layer 20, so that occurrence of a short circuit due to ion migration between two adjacent electrically-conductive layers 20 can be suppressed. In this case, in a plan view, at least one of the groove portions 30 may be provided between the two adjacent electrically-conductive layers 20.

<Groove Portion 30>

The groove portion 30 in the second surface 10b of the resin layer 10 can include a linear part that extends linearly in a plan view and/or a curvilinear part that extends curvilinearly in a plan view. The curvilinear part may be in the shape of a circle or ellipse or in the shape of an arc that is a part of a circle or ellipse.

The groove portion 30 has edges at the boundaries between the groove portion 30 and the planned electrically-conductive layer regions (herein, the first region R1 and the second region R2). In the example shown in FIG. 1B and FIG. 1C, the first groove portion 31 has the first edge e1 located on the first region R1 side and the second edge e2 located on the second region R2 side. The first edge e1 and the second edge e2 face each other. The first edge e1 and the second edge e2 may be substantially parallel to each other. The first edge e1 and the second edge e2 are parallel to the y axis. The width w of the first groove portion 31, i.e., the distance between the first edge e1 and the second edge e2, is preferably equal to or greater than 50 μm and equal to or smaller than 1000 μm, more preferably equal to or greater than 100 μm and equal to or smaller than 500 μm.

As shown in FIG. 1C and FIG. 1D, the groove portion 30 has the bottom P that includes a bottom surface f3 in a cross-sectional view. In this specification, the “bottom of a groove portion” refers to a part of the groove portion 30 that is closest to the +z side in a cross-sectional view taken along the width direction of the groove portion 30. The depth d2 of the groove portion 30 (maximum depth) is preferably equal to or greater than ⅓ and equal to or smaller than ⅔ of the thickness d1 of the resin layer 10. For example, the depth d2 is about ½ of the thickness d1. When the depth d2 of the groove portion 30 is within the above-described range, the creepage distance of insulation between the electrically-conductive layers 20 located at the both sides of the groove portion 30 can be large, so that ion migration can be effectively suppressed. In contrast, when the depth d2 of the groove portion 30 is equal to or smaller than ⅔ of the thickness d1 of the resin layer 10, the decrease in strength of the substrate 100, which is attributed to the partially-reduced thickness of the resin layer 10 because of the groove portion 30, can be suppressed. The depth d2 of the groove portion 30 may be, for example, equal to or greater than 130 μm and equal to or smaller than 600 μm.

The cross-sectional shape of the groove portion 30 is not particularly limited although, in the example shown in FIG. 1D, the cross-sectional shape of the first groove portion 31 includes a part of a rectangle. The first groove portion 31 has the bottom surface f3, a lateral surface f1 located between the bottom surface f3 and the first edge e1, and a lateral surface f2 located between the bottom surface f3 and the second edge e2. The bottom surface f3 may be substantially parallel to a portion of the second surface 10b exclusive of the groove portion 30 (substantially parallel to the xy plane). The lateral surfaces f1 and f2 may each be substantially perpendicular to the bottom surface f3 (perpendicular to the xy plane).

The groove portion 30 may include another groove portion in addition to the first groove portion 31. The width w, depth d2, and cross-sectional shape of the another groove portion may be the same as, or may be different from, those of the first groove portion 31.

<Configuration and Material of Resin Layer 10>

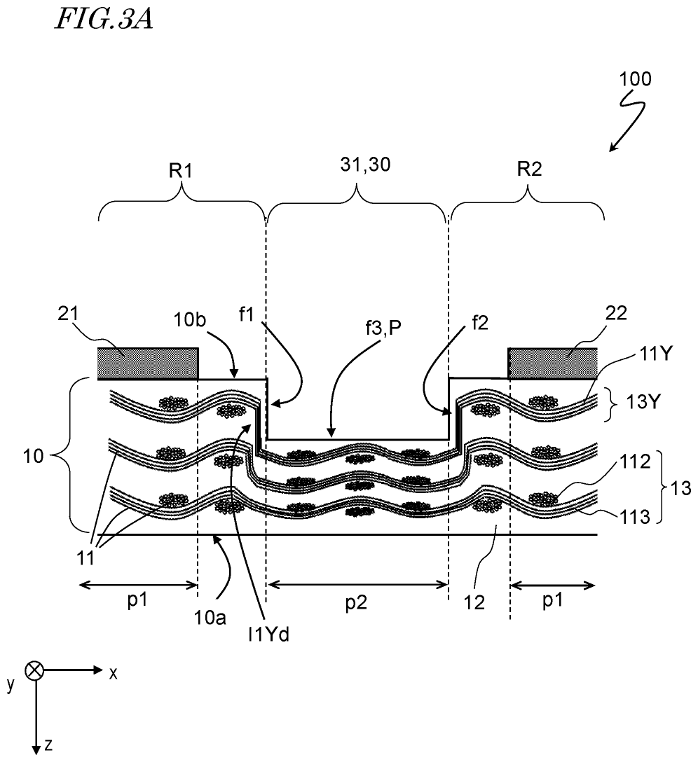

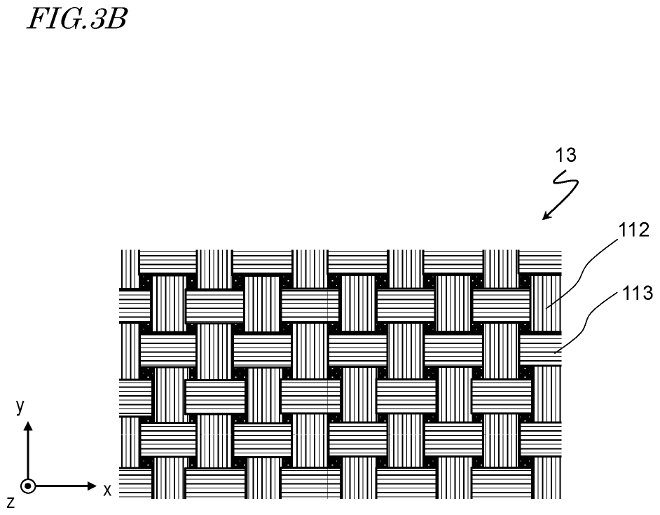

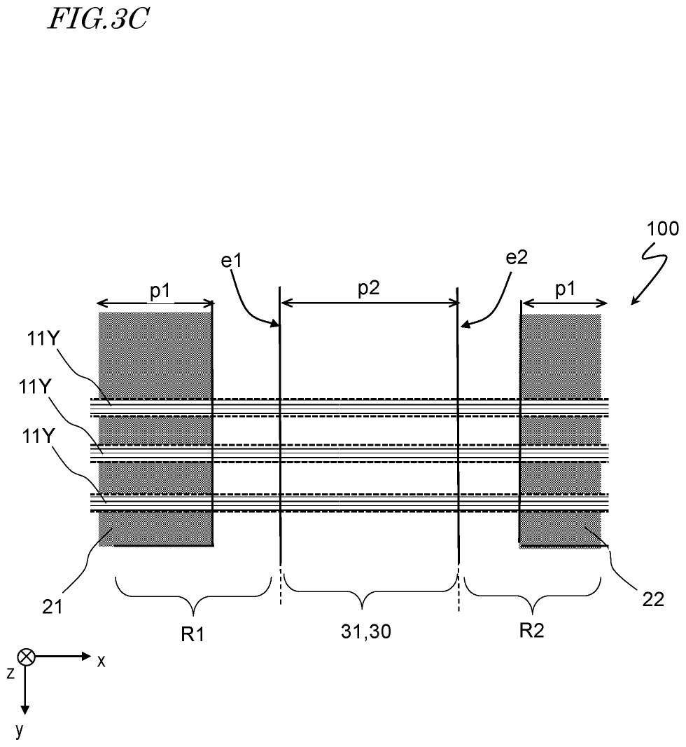

FIG. 3A is an enlarged cross-sectional view showing a part of the resin layer 10. FIG. 3A shows a cross section including the first groove portion 31, the first electrically-conductive layer 21 and the second electrically-conductive layer 22. FIG. 3B is an enlarged top view showing an example of a fiber layer 13 included in the resin layer 10. FIG. 3C is an enlarged bottom view showing a part of the substrate 100.

The resin layer 10 at least includes a plurality of fiber bundles 11 and a resin 12. The resin layer 10 is realized by reinforcing the resin 12 with the fiber bundles 11. Each of the fiber bundles 11 is a bundle including a plurality of fibers. The thickness of a single fiber is, for example, equal to or greater than 4 μm and equal to or smaller than 10 μm. In this example, the fiber bundles 11 include a plurality of longitudinal fiber bundles 112 that are substantially parallel to the y-axis direction and a plurality of transverse fiber bundles 113 that are substantially parallel to the x-axis direction. The longitudinal fiber bundles 112 and the transverse fiber bundles 113 are provided so as to intersect with each other in a plan view. In the illustrated example, the longitudinal fiber bundles 112 are provided along the y axis and the transverse fiber bundles 113 are provided along the x axis, although they are not limited to these arrangements.

The resin layer 10 may include at least one fiber layer 13 configured of a plurality of fiber bundles 11. Each fiber layer 13 may be fiber cloth formed by weaving together the longitudinal fiber bundles 112 and the transverse fiber bundles 113 as illustrated in FIG. 3B. The resin layer 10 preferably includes a plurality of fiber layers 13. As shown in FIG. 3A, the plurality of fiber layers 13 may be stacked up in the thickness direction of the resin layer 10 (z direction) with predetermined intervals therebetween.

The plurality of fiber bundles 11 include at least one continuous first fiber bundle 11Y located at a position shallower than the bottom P of the first groove portion 31. In a part of the resin layer 10 (herein, a part of the resin layer 10 in which the groove portion 30 is not provided), the first fiber bundle 11Y is located at a smaller depth along the +z direction from the second surface 10b of the resin layer 10 than the depth of the bottom P. The resin layer 10 preferably includes a plurality of first fiber bundles 11Y.

As shown in FIG. 3A and FIG. 3C, the first fiber bundles 11Y are provided so as to extend across the first region R1, the first groove portion 31 and the second region R2 inside the resin layer, in a cross-sectional view and in a plan view. That is, in a cross-sectional view and in a plan view, a part of a first fiber bundle 11Y overlapping the first region R1, another part of the first fiber bundle 11Y overlapping the first groove portion 31, and still another part of the first fiber bundle 11Y overlapping the second region R2 are connected together (continuous). In the illustrated example, the first fiber bundles 11Y meet the first edge e1 and the second edge e2 of the first groove portion 31.

In the present specification, in a plan view, parts p1 of the resin layer 10 overlapping the electrically-conductive layers 20 are referred to as “first portions,” and a part p2 of the resin layer 10 overlapping the groove portion 30 is referred to as “second portion.” In this example, parts of the resin layer 10 overlapping the first electrically-conductive layer 21 and the second electrically-conductive layer 22 are the first portions p1, and a part of the resin layer 10 overlapping the first groove portion 31 is the second portion p2. The thickness of the second portion p2 is smaller than that of the first portions p1 by, for example, the depth d2 of the first groove portion 31.

The first fiber bundles 11Y may extend across the first portions p1 and the second portion p2 in a plan view. As seen from FIG. 3A, the first fiber bundles 11Y in the first portions p1 of the resin layer 10 are located at a position shallower than the bottom P of the first groove portion 31, while the first fiber bundles 11Y in the second portion p2 are located between the bottom P of the first groove portion 31 and the first surface 10a of the resin layer 10. Accordingly, the surface of at least one groove portion 30 is defined by only the resin portion 12 of the resin layer 10. In a cross-sectional view, the first fiber bundles 11Y are bent in the depth direction of the first groove portion 31 (+z direction) along the first groove portion 31. As shown in the drawings, in a cross-sectional view including the first electrically-conductive layer 21, the first groove portion 31 and the second electrically-conductive layer 22, the first fiber bundles 11Y are bent in the +z direction along the lateral surfaces f1 and f2 of the first groove portion 31 and, thus, the first fiber bundles 11Y have a recessed portion 11Yd that is recessed in the +z direction.

The plurality of fiber layers 13 may include at least one first fiber layer 13Y located at a position shallower than the bottom P of the first groove portion 31. The first fiber layer 13Y may be continuously provided across the first region R1, the first groove portion 31 and the second region R2 in a plan view. For example, three or more fiber layers 13 may be stacked up in the resin layer 10. In this case, the strength of the resin layer 10 can be more effectively improved. One or some of the plurality of fiber layers 13 located at a position deeper than the bottom P of the first groove portion 31 may include fiber bundles 11 bent in the +z direction along the lateral surfaces f1 and f2 of the first groove portion 31.

The second surface 10b of the resin layer 10 can have a plurality of groove portions 30 that includes the first groove portion 31. The foregoing description has been provided based on an example of the configuration of fiber bundles 11 that overlap the first groove portion 31, the first region R1 and the second region R2 in a plan view, although fiber bundles 11 that overlap each of the plurality of groove portions 30 and planned electrically-conductive layer regions located on the opposite sides of the groove portion 30 in a plan view can also have the same configuration as that described above. That is, the plurality of fiber bundles 11 include at least one continuous first fiber bundle located at a position shallower than the bottom P of each groove portion 30, and the first fiber bundle may be provided so as to extend across the groove portion 30 and two planned electrically-conductive layer regions located on the both sides of the groove portion 30 in a plan view. The first fiber bundle may be bent in the depth direction (+z direction) along the groove portion 30 in a cross-sectional view.

The resin layer 10 includes the first portions p1 overlapping the first electrically-conductive layer 21 or the second electrically-conductive layer 22 in a plan view and the second portion p2 overlapping at least one groove portion 30 in a plan view. The second portion p2 of the resin layer 10 has a smaller thickness than the first portions p1 but can include an approximately equal number of fiber bundles 11 or an approximately equal number of fiber layers 13 to those included in the first portions p1. Therefore, the density of the fiber bundles 11 in the second portion p2 of the resin layer 10 can be greater than the density of the fiber bundles 11 in the first portions p1. Thus, the strength of the second portion p2 of the resin layer 10 can be secured.

At least one fiber bundle 11 may include two or more fiber bundles 11 that are stacked up in the thickness direction of the resin layer 10 between the first surface 10a and the second surface 10b of the resin layer 10. When the resin layer 10 includes the first portions p1 overlapping the first electrically-conductive layer 21 or the second electrically-conductive layer 22 in a plan view and the second portion p2 overlapping at least one groove portion 30 in a plan view, the stacking interval of the fiber bundles 11 in the second portion p2 of the resin layer 10 is preferably smaller than the stacking interval of the fiber bundles 11 in the first portions p1. It is preferred that, for example, two or more fiber layers 13 each including the fiber bundles 11 are stacked up in the thickness direction of the resin layer 10, and the stacking interval of the fiber layers 13 in the second portion p2 is smaller than the stacking interval of the fiber layers 13 in the first portions p1.

In the resin layer 10 of the present embodiment, the first fiber bundles 11Y located at a position shallower than the bottom P of the groove portion 30 are continuously provided so as to extend across the groove portion 30 in a plan view. That is, a part of the first fiber bundles 11Y is located between the groove portion 30 and the first surface 10a of the resin layer 10. The surface of the groove portion 30 is defined by only the resin 12 such that the fiber bundles 11 cannot be exposed, as is the second surface 10b of the resin layer 10 exclusive of the groove portion 30. Therefore, the entire second surface 10b of the resin layer 10 is smooth. The method of forming the resin layer 10 having such a configuration will be described later.

The resin layer 10 is a layer formed by curing a pre-preg as will be described later. In this specification, the pre-preg is a material provided by impregnating fiber bundles with a thermosetting resin. The thermosetting resin in the pre-preg is in a state called B stage, in which the resin is not yet fully cured. B stage means that the thermosetting resin is semi-cured. The semi-cured resin can be once melted by increasing the temperature and, thereafter, application of heat can cause a curing reaction of the resin so that the resin can be fully cured.

The type of the resin 12 in the resin layer 10 is not particularly limited. The resin 12 can be an epoxy resin, polyimide resin, phenol resin or melamine resin, or a combination thereof.

The material of the fiber bundles 11 is not particularly limited. The material of the fiber bundles 11 can be glass fiber, ceramic fiber, carbon fiber or aramid fiber, or a combination thereof. The resin layer 10 of the present embodiment is preferably a glass epoxy resin layer formed by impregnating glass fiber cloth with an epoxy resin and performing a heat curing treatment on the resultant cloth.

The resin layer 10 may further include an inorganic filler of high thermal conductivity such that the resin layer 10 can have a heat radiation function. The inorganic filler can be silica, alumina, aluminum nitride, boron nitride, silicon carbide, magnesium oxide, zinc oxide, aluminum hydroxide, or the like.

[Electrically-Conductive Layers 20]

The electrically-conductive layers 20 include at least a pair of positive and negative electrically-conductive layers, through which power is supplied to a light source section (described later) placed on the first surface 10a of the resin layer 10. The electrically-conductive layers 20 are electrically connected to, for example, an external circuit or power supply.

In the example illustrated in FIG. 1B and FIG. 1C, the planar shape of each electrically-conductive layer 20 is substantially rectangular. The size of the rectangle in a plan view is, for example, 6 mm×6 mm. Note that the size of the electrically-conductive layers 20 may be smaller than the planned electrically-conductive layer regions on which the electrically-conductive layers 20 are to be provided (herein, the first region R1 and the second region R2). The planar shape of the electrically-conductive layers 20 is not limited to rectangular shapes. As shown in the drawings, some of the electrically-conductive layers 20 may have a cutaway portion at a corner such that the polarity of the electrically-conductive layers 20 can be identified. Each of the electrically-conductive layers 20 can have a planar shape substantially similar or conformable to a corresponding planned electrically-conductive layer region R1, R2. Further, the planar shape or size of the plurality of electrically-conductive layers 20 may be the same or may be different.

As shown in FIG. 1B, the plurality of electrically-conductive layers 20 are provided on the second surface 10b of the resin layer 10 so as to be spaced away from each other. In this example, the first electrically-conductive layer 21 and the second electrically-conductive layer 22 are provided as the electrically-conductive layers 20. Note that three or more electrically-conductive layers 20 may be provided on the second surface 10b. Each of the electrically-conductive layers 20 is provided on either of a plurality of planned electrically-conductive layer regions in the second surface 10b. Preferably, a single electrically-conductive layer 20 is provided on a single planned electrically-conductive layer region. Preferably, each of the electrically-conductive layers 20 is located away from the edges of the groove portion 30 in a plan view.

Preferably, the shortest distance L1 between two adjacent electrically-conductive layers 20 in a plan view is, for example, equal to or greater than 50 μm. In this case, occurrence of a short circuit due to ion migration between these electrically-conductive layers 20 can be more effectively suppressed. The upper limit of the shortest distance L1 between the electrically-conductive layers 20 is not particularly limited but may be, for example, equal to or smaller than 1000 μm from the viewpoint of reducing the size of the light emitting device.

[Upper Electrically-Conductive Layers 40]

As shown in FIG. 1A and FIG. 1C, the substrate 100 may further include a plurality of upper electrically-conductive layers 40 on the first surface 10a of the resin layer 10.

The plurality of upper electrically-conductive layers 40 include at least a pair of positive and negative electrically-conductive layers and can be electrically connected to the electrodes of a light source section placed on the upper surface 100a side of the substrate 100, which will be described later. Each of the upper electrically-conductive layers 40 is electrically connected to, for example, a corresponding one of the electrically-conductive layers 20 via an electrical conductor 50 provided in a through-hole of the resin layer 10. In a plan view, each of the upper electrically-conductive layers 40 may be provided so as to overlap at least a part of a corresponding one of the electrically-conductive layers 20.

In the example illustrated in FIG. 1A, the planar shape of each of the upper electrically-conductive layers 40 is substantially rectangular. The size of the rectangle is, for example, 3 mm×1 mm. Note that the planar shape, size, and arrangement of the upper electrically-conductive layers 40 can be selected according to the shape, size, and arrangement of the positive and negative electrodes of the light emitting element. The planar shape and size of the plurality of upper electrically-conductive layers 40 may be the same or may be different.

In the present embodiment, the plurality of upper electrically-conductive layers 40 include the first upper electrically-conductive layer 41 and the second upper electrically-conductive layer 42. The first upper electrically-conductive layer 41 and the second upper electrically-conductive layer 42 are provided on the first surface 10a of the resin layer 10 so as to be spaced away from each other. The first upper electrically-conductive layer 41 is electrically connected to the first electrically-conductive layer 21 provided on the second surface 10b of the resin layer 10. Likewise, the second upper electrically-conductive layer 42 is electrically connected to the second electrically-conductive layer 22. The material of the lower electrically-conductive layers 20 and the upper electrically-conductive layers 40 can be a metal selected from the group consisting of Cu, Ag, Au, Ni, Fe and Al, or at least one type of alloys containing these metals as a major constituent. In the present embodiment, the lower electrically-conductive layers 20 are, for example, Cu layers plated with Au. The thickness of the electrically-conductive layers 20 is, for example, equal to or greater than 10 μm and equal to or smaller than 110 μm. The upper electrically-conductive layers 40 are, for example, Cu layers covered by an Au film. The thickness of the upper electrically-conductive layers 40 is, for example, equal to or greater than 10 μm and equal to or smaller than 110 μm.

[Electrical Conductor 50]

As shown in FIG. 1A, FIG. 1B and FIG. 1C, the substrate 100 may further include a plurality of electrical conductors 50. Each of the electrical conductors 50 is provided in a through-hole penetrating through the resin layer 10 in the thickness direction. Each of the electrical conductors 50 is in contact with a corresponding one of the electrically-conductive layers 20 and a corresponding one of the upper electrically-conductive layers 40 such that these electrically-conductive layers 20 and the upper electrically-conductive layers 40 are electrically connected together. The electrical conductors 50 are, for example, Cu layers. The electrical conductors 50 preferably fill the through-holes of the resin layer 10 but may be provided only on the lateral surface of the through-holes.

In the illustrated example, the electrical conductors 50 include the first electrical conductor 51 and the second electrical conductor 52. The first electrical conductor 51 electrically connects the first electrically-conductive layer 21 and the first upper electrically-conductive layer 41. The second electrical conductor 52 electrically connects the second electrically-conductive layer 22 and the second upper electrically-conductive layer 42.

(First Substrate 1000)

The substrate of the present embodiment may be a substrate having a plurality of unit regions (hereinafter, referred to as “first substrate”). The first substrate 1000 can be divided or singulated into individual pieces corresponding to the unit regions, whereby a plurality of substrates 100 are obtained. Note that, in this specification, the term “substrate for light emitting elements” involves not only the substrates obtained after the singulation but also the first substrate before the singulation.

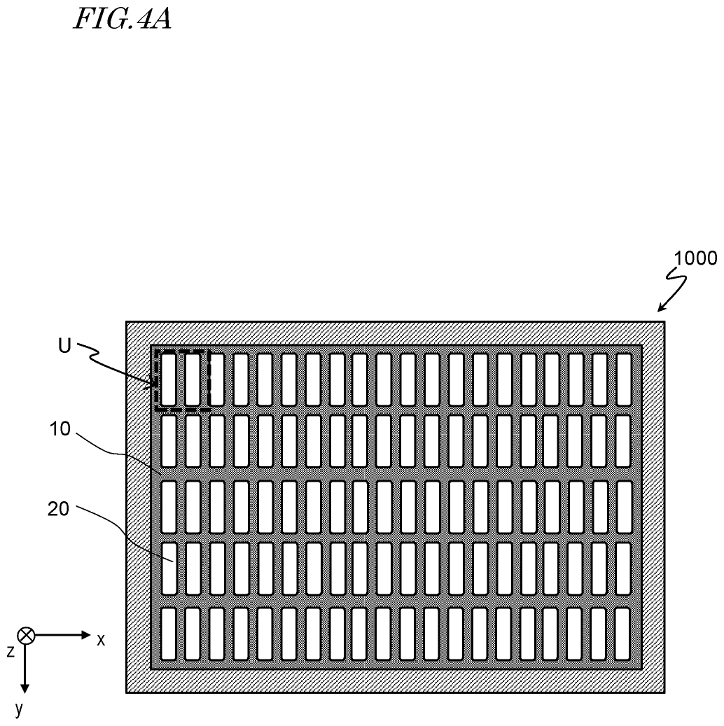

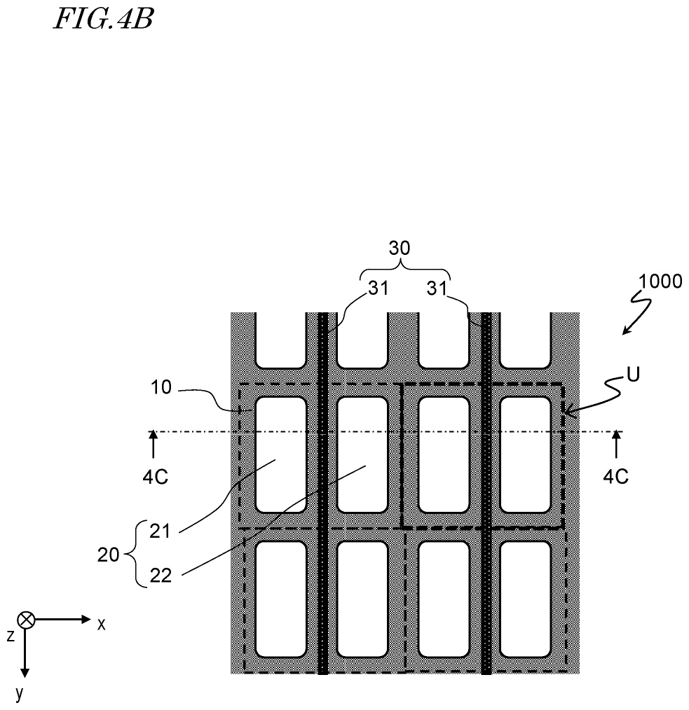

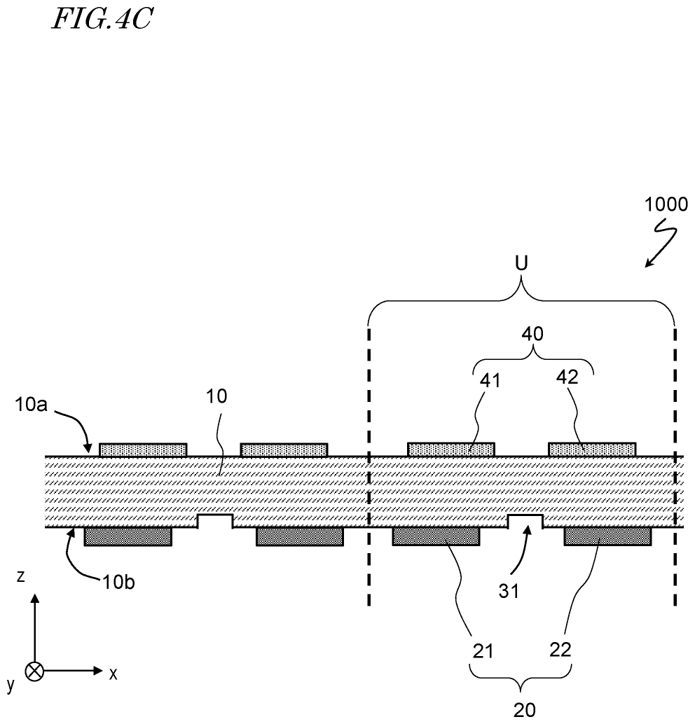

FIG. 4A is a schematic bottom view showing an example of the first substrate 1000. FIG. 4B is an enlarged bottom view showing a part of the first substrate 1000. FIG. 4C is an enlarged cross-sectional view of the first substrate 1000 taken along line 4C-4C shown in FIG. 4B.

The first substrate 1000 includes a plurality of unit regions U that are two-dimensionally arrayed. In the illustrated example, the plurality of unit regions U are aligned in the x direction and the y direction.

The first substrate 1000 includes a resin layer 10 that has a first surface 10a and a second surface 10b. The resin layer 10 is continuous across the plurality of unit regions U. In each of the unit regions U, a plurality of upper electrically-conductive layers 40 are provided on the first surface 10a of the resin layer 10, and a first electrically-conductive layer 21 and a second electrically-conductive layer 22 are provided on the second surface 10b. In each of the unit regions U, the second surface 10b of the resin layer 10 has a first groove portion 31. In the illustrated example, in each of the unit regions U, the shape and arrangement of the electrically-conductive layers 20, the upper electrically-conductive layers 40 and the groove portion 30 are, for example, the same as or similar to those in the substrate 100 illustrated in FIG. 1A, FIG. 1B and FIG. 1C.

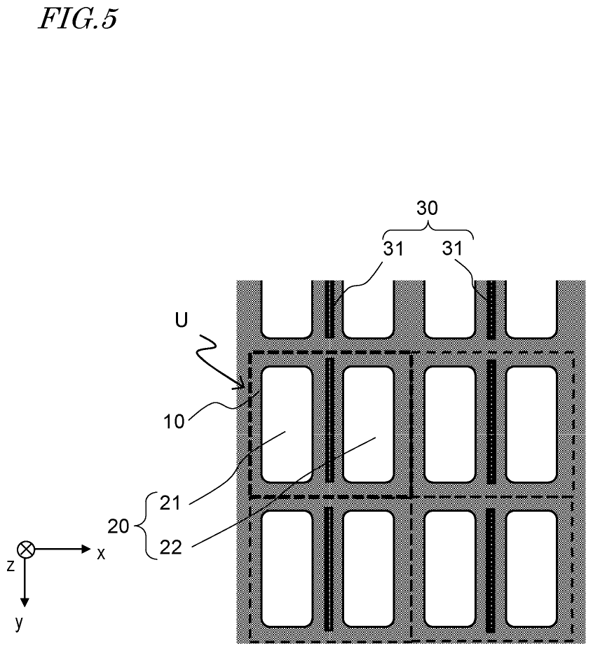

The groove portion 30 in each of the unit regions U may be in communication with the groove portions 30 in the neighboring unit regions U. In this example, the first groove portions 31 of two-unit regions U that neighbor each other in the y direction are in communication with each other. As shown in the drawings, the first groove portions 31 may be provided continuously in the y direction across the first substrate 1000. Alternatively, as illustrated in FIG. 5, the first groove portions 31 of the unit regions U may be provided so as to be spaced away from one another. Note that, in the first substrate 1000 shown in FIG. 4A, FIG. 4B, FIG. 4C and FIG. 5, the through-holes penetrating through the resin layer 10 in the thickness direction and the electrical conductors 50 are not shown.

(Light Emitting Device 400)

Next, an example of a light emitting device 400, which includes the substrate 100 of the present embodiment, is described with reference again to FIG. 2A and FIG. 2B.

The light emitting device 400 includes a substrate 100 and a light source section 200.

[Light Source Section 200]

The light source section 200 is provided on the upper surface 100a side of the substrate 100. The light source section 200 has a light emission surface 200a located opposite to the substrate 100.

In the present embodiment, the light source section 200 includes at least one light emitting element 70, which includes the first light emitting element 71. The light emitting element 70 is located on the upper surface 100a side of the substrate 100, i.e., the first surface 10a side of the resin layer 10. In the illustrated example, only the first light emitting element 71 is provided on the upper surface 100a of the substrate 100, although two or more light emitting elements 70 may be two-dimensionally arrayed on the upper surface 100a.

<Light Emitting Element 70>

As shown in FIG. 2B, the light emitting element 70 has a light exit surface 70a from which large part of light exits, an electrode-formation surface 70b located opposite to the light exit surface 70a, and lateral surfaces 70c connected to the light exit surface 70a and the electrode-formation surface 70b. The light emitting element 70 includes at least a pair of positive and negative electrodes 81 and 82 located on the electrode-formation surface 70b. In the illustrated example, the light exit surface 70a of the light emitting element 70 is identical with the light emission surface 200a of the light source section 200. The electrodes 81 and 82 are each electrically connected to a corresponding one of the upper electrically-conductive layers 40 via a bonding material, such as solder, electrically-conductive paste, or the like. In this example, the electrode 81 is electrically connected to the first upper electrically-conductive layer 41 while the electrode 82 is electrically connected to the second upper electrically-conductive layer 42.

The shape of the light emitting element 70 in a plan view is, for example, rectangular. The size of the light emitting element 70 is not particularly limited. The longitudinal and transverse dimensions of the light emitting element 70 are, for example, equal to or smaller than 5 mm, preferably equal to or smaller than 4 mm. More preferably, the longitudinal and transverse dimensions of the light emitting element 70 are equal to or smaller than 3 mm. In the present embodiment, in a plan view, the light emitting element 70 has a square shape of 3 mm on each side.

The light emitting element 70 can be selected from various types of light emitting elements, including semiconductor lasers, light-emitting diodes, etc. In the present embodiment, the light emitting element 70 is, for example, a light-emitting diode that includes a light-transmitting substrate, such as sapphire substrate, and a semiconductor multilayer body stacked on the light-transmitting substrate. The wavelength of light to be emitted from the light emitting element 70 is discretionary selectable. For example, light emitting elements including a nitride semiconductor (InₓAl_{y}Ga_{1-x-y}N, 0≤X, 0≤Y, X+Y≤1), or a semiconductor such as ZnSe and GaP, can be used as blue and green light emitting elements. Light emitting elements including a semiconductor such as GaAlAs, AlInGaP, or the like, can be used as red light emitting elements.

Semiconductor light emitting elements including other materials than those mentioned above can also be used. The composition of the materials in the light emitting elements used, the color of light to be emitted from the light emitting elements, and the size and number of the light emitting elements may be appropriately selected according to what the light emitting elements are applied to. As will be described later, when the light source section 200 includes a wavelength conversion layer, the emission layer of the light emitting element 70 preferably emits light at such a short wavelength that the light can efficiently excite a wavelength converting substance contained in the wavelength conversion layer.

The electrodes 81, 82 are made of a known metal material that can be electrically connected to the semiconductor multilayer body. The material of the electrodes 81, 82 can be, for example, at least one type of metal selected from Ni, Pt, Cu, Au, Ag, AuSn, and the like. The shape of the electrodes 81, 82 in a plan view is not particularly limited but may be appropriately selected from rectangular, polygonal, circular, and elliptical shapes.

[Other Examples of Light Source Section]

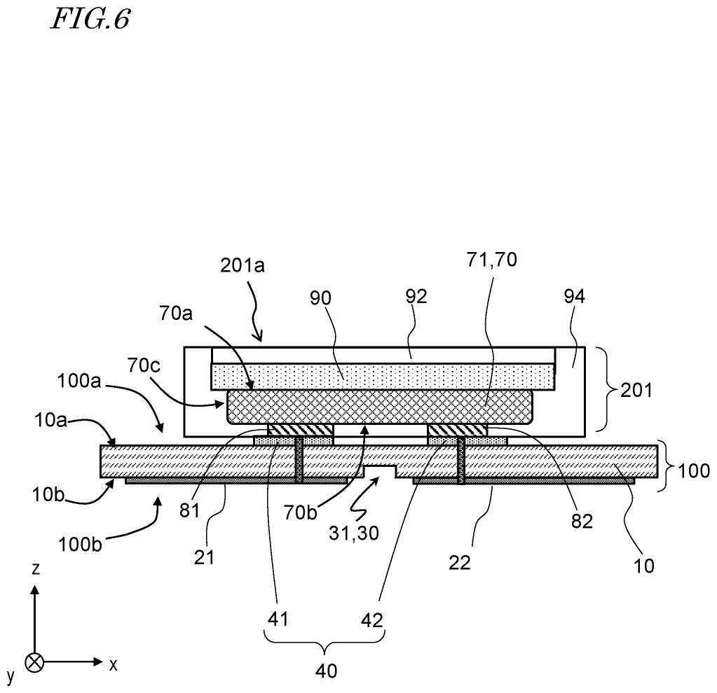

The configuration of the light source section is not limited to the example shown in FIG. 2A and FIG. 2B. FIG. 6 is a cross-sectional view for illustrating the substrate 100 and another light source section 201 according to the present embodiment.

The light source section 201 includes a light emitting element 70 (herein, first light emitting element 71), a wavelength conversion layer 90, a diffusing layer 92, and a reflector 94. The light source section 201 has a light emission surface 201a located on or above (+x direction) the light exit surface 70a of the light emitting element 70. In this example, the light source section 201 includes only a single light emitting element 70, although the light source section 201 may include a plurality of light emitting elements 70 that are two-dimensionally arrayed.

<Wavelength Conversion Layer 90>

The wavelength conversion layer 90 is located on or above (+z direction) the light exit surface 70a of the light emitting element 70. The wavelength conversion layer 90 absorbs at least part of light emitted from the light emitting element 70 such that light exiting from the wavelength conversion layer 90 has a different wavelength from that of the light emitted from the light emitting element 70.

The wavelength conversion layer 90 may have a substantially rectangular shape in a plan view. Preferably, in a plan view, the wavelength conversion layer 90 is larger than the light exit surface 70a of the light emitting element 70 and covers the entire light exit surface 70a. In this case, the light emitted from the light emitting element 70 can efficiently enter the wavelength conversion layer 90, and the light exiting from the wavelength conversion layer 90 can have a converted wavelength.

In the present embodiment, the wavelength conversion layer 90 is in the shape of, for example, a square of 3.2 mm on each side in a plan view. The thickness in the z-axis direction of the wavelength conversion layer 90 is, for example, 40 μm.

The wavelength conversion layer 90 contains, for example, a resin as the basic material, and a wavelength converting substance dispersed in the resin. The basic material can be, for example, a light-transmitting material, such as epoxy resin, silicone resin, or a mixture thereof, or glass. From the viewpoint of light resistance and easy moldability, the basic material of the wavelength conversion layer 90 is preferably a silicone resin. Particularly preferably, the basic material contains a phenyl silicone resin as a major constituent. The wavelength conversion layer 90 may be made of a ceramic or glass material (major material) in which a wavelength converting substance is contained.

The wavelength converting substance is excited by light emitted from the light emitting element 70 to emit light having a different wavelength from that of the light emitted from the light emitting element 70. Examples of the wavelength converting substance include yttrium aluminum garnet (YAG)-based phosphors activated with cerium (e.g., Y₃(Al,Ga)₅O₁₂:Ce), lutetium aluminum garnet (LAG)-based phosphors activated with cerium (e.g., Lu₃(Al,Ga)O₁₂:Ce), terbium aluminum garnet-based phosphors (e.g., Tb₃ (Al, Ga)₅O₁₂: Ce), nitrogen-containing calcium aluminosilicate (CaO—Al₂O₃—SiO₂)-based phosphors activated with europium and/or chromium, silicate ((Sr,Ba)₂SiO₄)-based phosphors activated with europium, β sialon-based phosphors (e.g., (Si,Al)₃(O,N)₄:Eu), α sialon-based phosphors (e.g., M_{z}(Si,Al)₁₂(O,N)₁₆ (where 0<z≤2 and M is Li, Mg, Ca, Y, or a lanthanide element other than La and Ce)), nitride-based phosphors such as CASN-based phosphors (e.g., CaAlSiN₃:Eu) or SCASN-based phosphors (e.g., (Sr,Ca)AlSiN₃:Eu), fluoride-based phosphors such as KSF-based phosphors (e.g., K₂SiF₆:Mn⁴⁺) or MGF-based phosphors (e.g., 3.5MgO.0.5MgF₂. GeO₂:Mn), sulfide-based phosphors, perovskite, chalcopyrite, and quantum dots. The other types of phosphors than those mentioned above can also be used so long as they have similar properties, functions, and effects. The wavelength conversion layer 90 may contain only one type of the aforementioned wavelength converting substances but preferably contains a plurality of types of wavelength converting substances. For example, the wavelength conversion layer 90 preferably contains a LAG-based phosphor capable of emission of greenish light and a CASN-based phosphor capable of emission of reddish light. In this case, the light source section 201 capable of emission of white light can be realized. Because a plurality of types of wavelength converting substances are contained, the wavelength band can be enlarged, and occurrence of a wavelength range of low emission intensity can be suppressed. The amount of the wavelength converting substances contained in the wavelength conversion layer 90 is, for example, 10 to 80 weight %. Note that, in this specification, the term “weight %” means the proportion of the weight of a substance (herein, wavelength converting substance) contained in a basic material with respect to the total weight of the basic material and the contained substance.

The wavelength conversion layer 90 may contain a material other than the wavelength converting substance. For example, a material whose refractive index is different from that of the basic material may be dispersed in the wavelength conversion layer 90. For example, particles capable of diffusing light, such as titanium oxide or silicon oxide particles, may be dispersed in the basic material of the wavelength conversion layer 90.

<Diffusing Layer 92>

The diffusing layer 92 may be located on or above (+z direction) the wavelength conversion layer 90. The diffusing layer 92 diffuses light emitted from the light emitting element 70.

The diffusing layer 92 may have a substantially rectangular shape in a plan view. Preferably, in a plan view, the diffusing layer 92 is larger than the light exit surface 70a of the light emitting element 70 and covers the entire light exit surface 70a. The size of the diffusing layer 92 may be substantially equal to the size of the wavelength conversion layer 90. In the present embodiment, the diffusing layer 92 is in the shape of, for example, a square of 3.2 mm on each side in a plan view. The thickness in the z-axis direction of the diffusing layer 92 is, for example, 30 μm.

The diffusing layer 92 includes a resin as the basic material and a diffusing material dispersed in the resin. The basic material can be a light-transmitting material, such as epoxy resin, silicone resin, or a mixture thereof, or glass. From the viewpoint of light resistance and easy moldability, the basic material of the diffusing layer 92 is preferably a silicone resin. Particularly preferably, the basic material contains a phenyl silicone resin as a major constituent. When the basic material of the diffusing layer 92 is the same resin as that of the wavelength conversion layer 90, the adhesion between the wavelength conversion layer 90 and the diffusing layer 92 can be improved. The diffusing layer 92 may be formed of a ceramic or glass material (major material) in which the diffusing material is contained.

The diffusing material may be, for example, a high-reflectance material, such as white filler of titanium oxide, silicon oxide, alumina, zinc oxide, or the like. The concentration of the diffusing material is preferably equal to or higher than 0.1 weight % and equal to or lower than 3.0 weight %. The diffusing layer 92 may further contain a glass filler, or the like, in order to suppress expansion and shrinkage of the basic material resin due to heat. The concentration of the glass filler is preferably equal to or higher than 50 weight % and equal to or lower than 80 weight %. Note that the concentrations of the diffusing material and the glass filler are not limited to these examples. The diffusing layer 92 preferably contains titanium oxide and a glass filler.

<Reflector 94>

The reflector 94 covers at least the lateral surfaces 70c of the light emitting element 70, the electrode-formation surface 70b, the lateral surfaces of the electrodes 81, 82, the lateral surfaces of the wavelength conversion layer 90, and the lateral surfaces of the diffusing layer 92.

The reflector 94 reflects light emitted from the lateral surfaces 70c of the light emitting element 70 such that the reflected light travels toward a side above the light emitting element 70 (in the +z direction). The reflector 94 also reflects light traveling from the electrode-formation surface 70b of the light emitting element 70 toward the substrate 100 side such that the reflected light travels toward a side above the light emitting element 70 (in the +z direction). Thus, the utilization efficiency of the light emitted from the light emitting element 70 can be improved.

The reflector 94 includes a resin as the basic material and a reflective substance dispersed in the resin. The basic material can be a light-transmitting material, such as epoxy resin, silicone resin, or a mixture thereof. From the viewpoint of light resistance and easy moldability, the basic material of the reflector 94 is preferably a silicone resin. When the basic material of the reflector 94 is the same resin as those of the wavelength conversion layer 90 and the diffusing layer 92, the adhesion to the wavelength conversion layer 90 and the diffusing layer 92 can be improved.

Examples of the reflective substance include titanium oxide, silicon oxide, zirconium oxide, yttrium oxide, yttria-stabilized zirconia, potassium titanate, alumina, aluminum nitride, boron nitride, and mullite. The concentration of the reflective substance in the reflector 94 is preferably equal to or higher than 10 weight % and equal to or lower than 70 weight %. The reflector 94 may further contain a glass filler, or the like, in order to suppress expansion and shrinkage of the basic material resin due to heat. The concentration of the glass filler is preferably higher than 0 weight % and lower than 30 weight %, more preferably equal to or higher than 5 weight % and equal to or lower than 20 weight %. Note that the concentrations of the reflective substance and the glass filler are not limited to these examples. The reflector 94 preferably contains titanium oxide and a glass filler.

[Lens Unit 300]

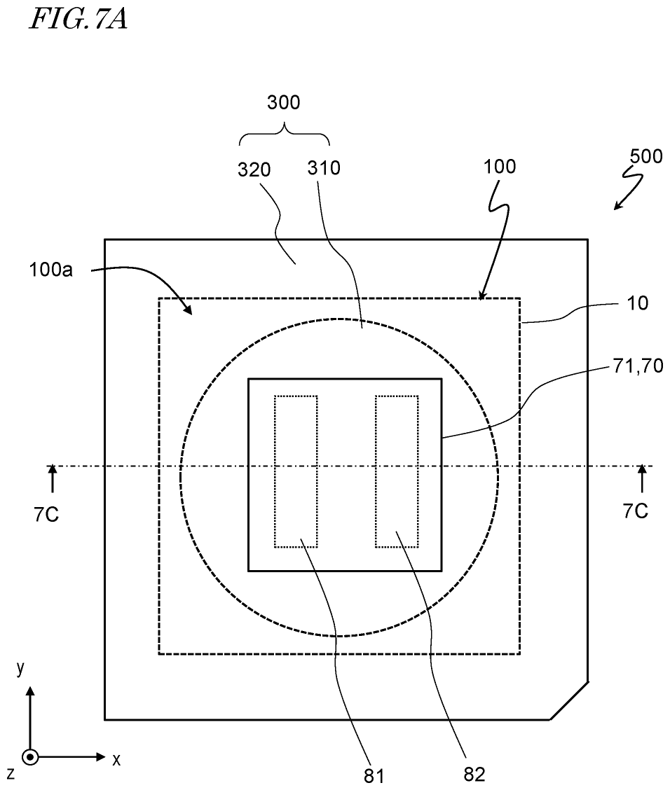

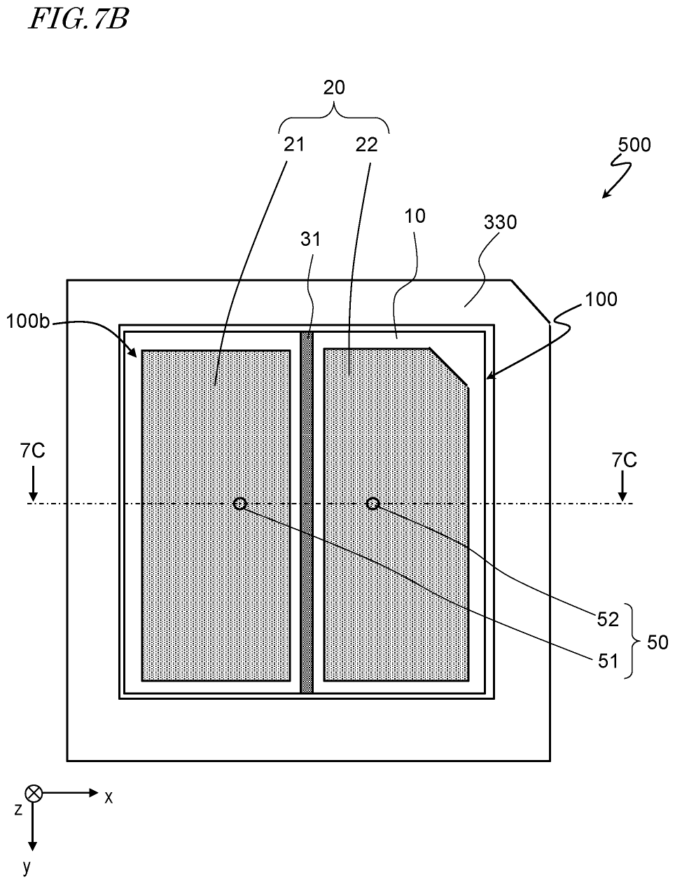

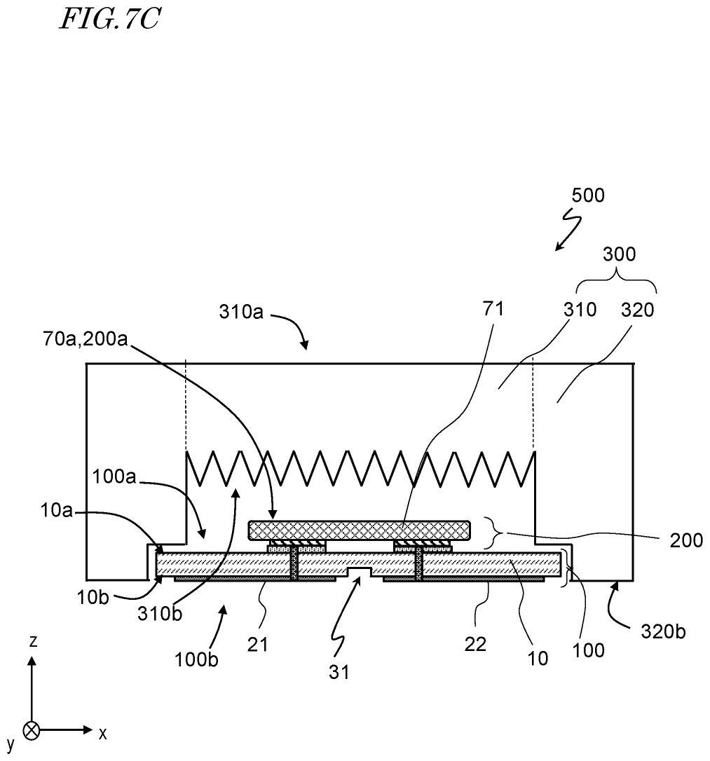

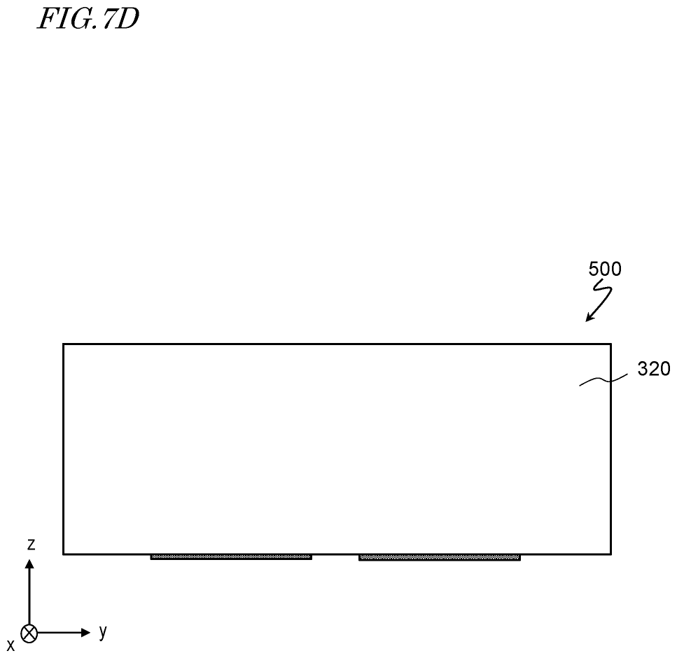

The light emitting device of the present embodiment may be a light emitting device 500 that further includes a lens 300. An example of the light emitting device 500 is now described that includes the substrate 100 of the present embodiment. FIG. 7A is a schematic top view of the light emitting device 500. FIG. 7B is a schematic bottom view of the light emitting device 500. FIG. 7C is a schematic cross-sectional view of the light emitting device 500 taken along line 7C-7C shown in FIG. 7A and FIG. 7B. FIG. 7D is a schematic lateral side view of the light emitting device 500 as viewed in the +y axis direction.

The lens 300 includes a lens section 310 and a lens holder 320 located outside the lens section 310 so as to surround the periphery of the lens section 310. The lens holder 320 is continuously (integrally) formed with the lens section 310.

As shown in FIG. 7A, FIG. 7B and FIG. 7C, the lens 300 is provided so as to cover the light source section 200. As shown in the drawings, the lens 300 may cover the upper surface 100a and the lateral surfaces of the substrate 100 while the lower surface 100b of the substrate 100 is exposed.

The lens 300 may be formed of a light-transmitting resin. The light-transmitting resin can be a thermoplastic resin, such as polycarbonate, acrylic resins, cyclic polyolefin, polyethylene terephthalate, and polyester, or a thermosetting resin, such as phenolic resins, urea resins, melamine resins, epoxy resins, silicone resins, and polyurethane. Among these examples, polycarbonate is preferred.

<Lens Portion 310>

The lens section 310 is located on or above (+z direction) the light emission surface 200a of the light source section 200 (herein, the light exit surface 70a of the light emitting element 70). The lens section 310 is an optical function section capable of refracting light emitted from the light source section 200 and transmitted through the lens section 310 such that the light exiting from the lens section 310 travels in the +z direction. The lens section 310 preferably covers the entire light emission surface 200a in a plan view. The lens section 310 may be a convex lens, such as biconvex lens, plano-convex lens, and convex meniscus lens, a concave lens, such as biconcave lens, plano-concave lens, and concave meniscus lens, or a Fresnel lens.

In the present embodiment, the contour of the lens section 310 in a plan view is substantially circular. The diameter of the lens section 310 is preferably equal to or greater than 6 mm and equal to or smaller than 8 mm, and may be about 6.8 mm, for example. The thickness of the lens section 310 is preferably equal to or greater than 1 mm and equal to or smaller than 2 mm, and may be about 1.5 mm, for example. Note that the contour of the lens section 310 in a plan view is not particularly limited but may have a polygonal shape, such as tetragon, hexagon or octagon.

The lens section 310 has a light entry surface 310b located on the light emission surface 200a side of the light source section 200 and a light exit surface 310a located on the side (+z side) opposite to the light entry surface 310b. In the present embodiment, the light entry surface 310b of the lens section 310 has a Fresnel shape. The center of the lens section 310 is coincident with the center of the light emission surface 200a (herein, the light exit surface 70a of the first light emitting element 71). Meanwhile, the light exit surface 310a of the lens section 310 is substantially flat. In this example, the term “the light exit surface of the lens section” refers to a part of the lens 300 overlapping the light entry surface 310b in a plan view. When the lens section 310 has a Fresnel shape, the thickness of the lens 300 can be reduced. Accordingly, the thickness of the light emitting device 500 can be reduced.

<Lens Holder 320>

The lens holder 320 is a member for holding the lens section 310. The lens holder 320 is continuous at the periphery of the lens section 310 and is elongated downward (in the −z direction). In this example, the lens holder 320 has a cylindrical shape in a plan view. The thickness in the x-axis direction or the y-axis direction of the lens holder 320 is, for example, equal to or greater than 0.3 mm and equal to or smaller than 1.0 mm. The height in the z direction of the lens holder 320, i.e., the distance from the upper end of the lens holder 320 (in other words, the light exit surface 310a) to the lower end of the lens holder 320, is for example equal to or greater than 1.0 mm and equal to or smaller than 5.0 mm, and can be adjusted such that an air layer can be formed between the light entry surface 310b of the lens section 310 and the light emission surface 200a of the light source section 200.

The lower surface 320b of the lens holder 320 is preferably coplanar with the lower surface 100b of the substrate 100 or located at a position lower than the lower surface 100b. In a cross-sectional view, the lens holder 320 may be spaced away from the substrate 100.

In this example, in a plan view, the periphery of the lens holder 320 has a tetragonal shape, and the size of the tetragon is, for example, 8 mm×8 mm. The shape of the periphery of the lens holder 320 in a plan view is not particularly limited but may be circular, elliptical, or polygonal. The lens holder 320 may have a cutaway portion in at least one corner such that the orientation of the light emitting device 500 can be identified.

When the light source section 200 includes a plurality of light emitting elements 70 that are two-dimensionally arrayed, the center of the lens section 310 may be aligned with the center of the substrate. When the lens section 310 includes a plurality of Fresnel lenses and the plurality of light emitting elements 70 are provided so as to form one-to-one pairs with the Fresnel lenses, the center of each of the Fresnel lenses may be aligned with the center of a corresponding one of the light emitting elements 70.

(Method of Producing Substrate for Light Emitting Elements)

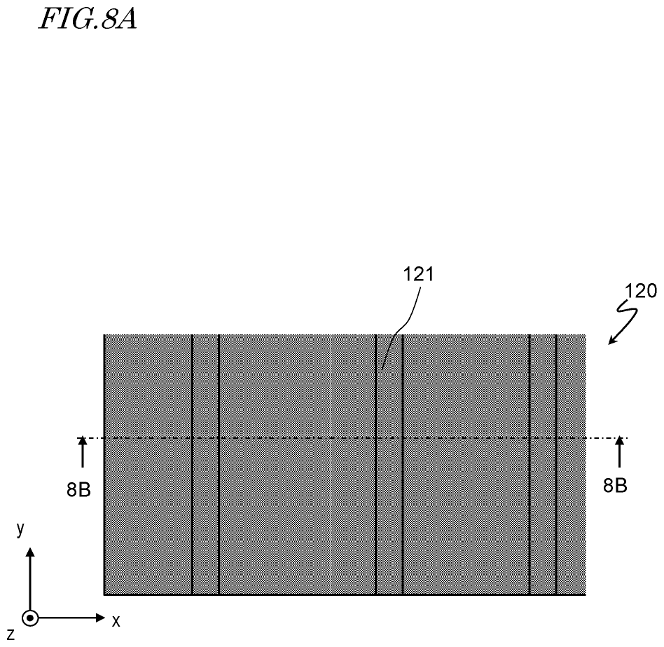

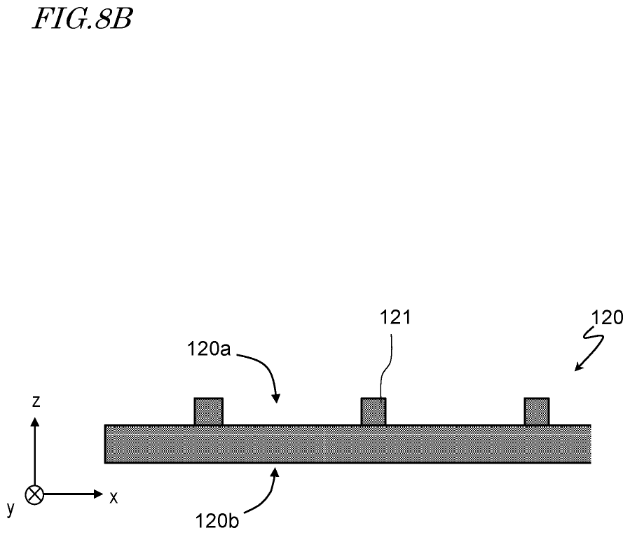

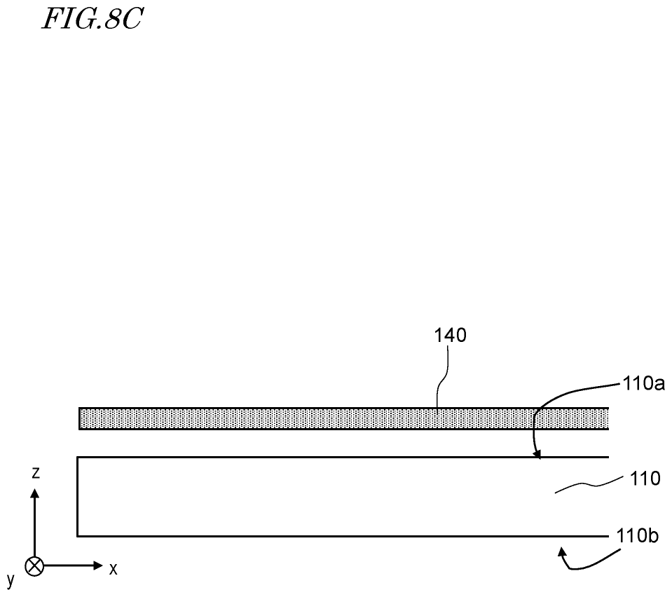

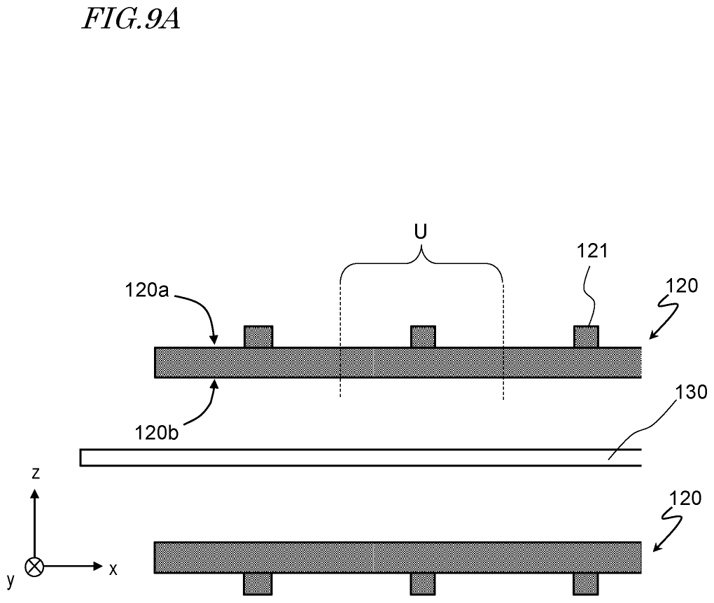

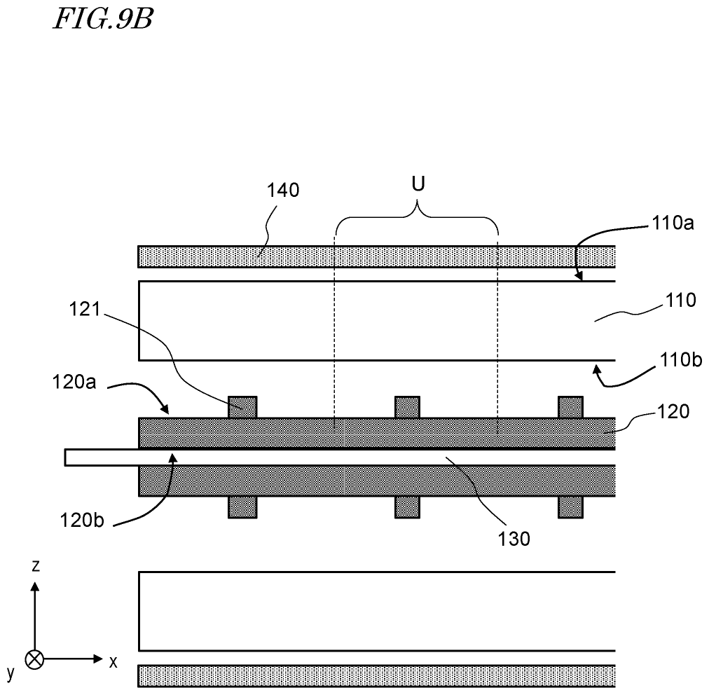

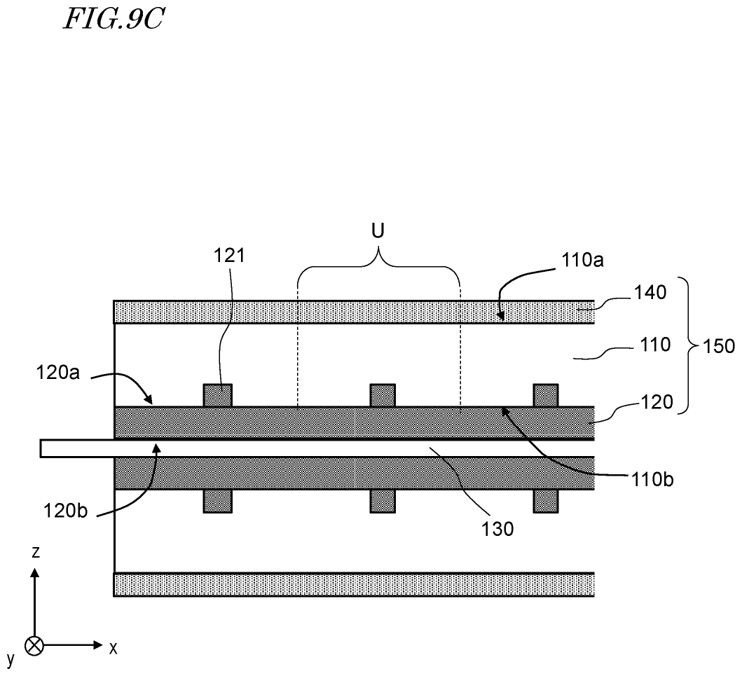

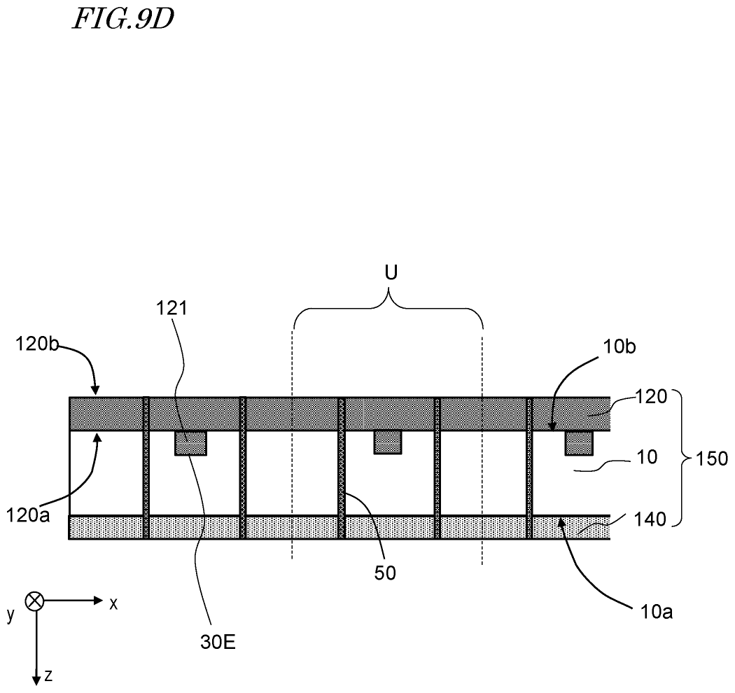

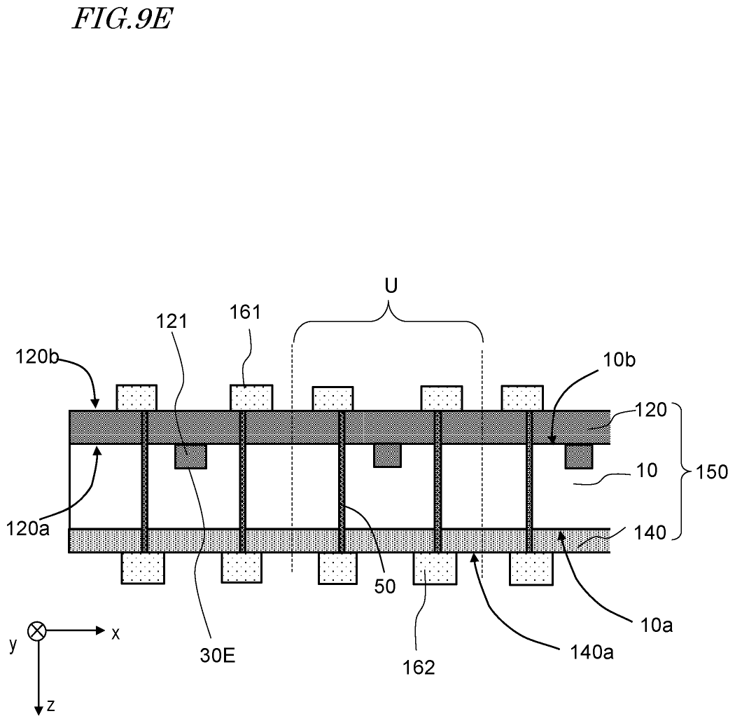

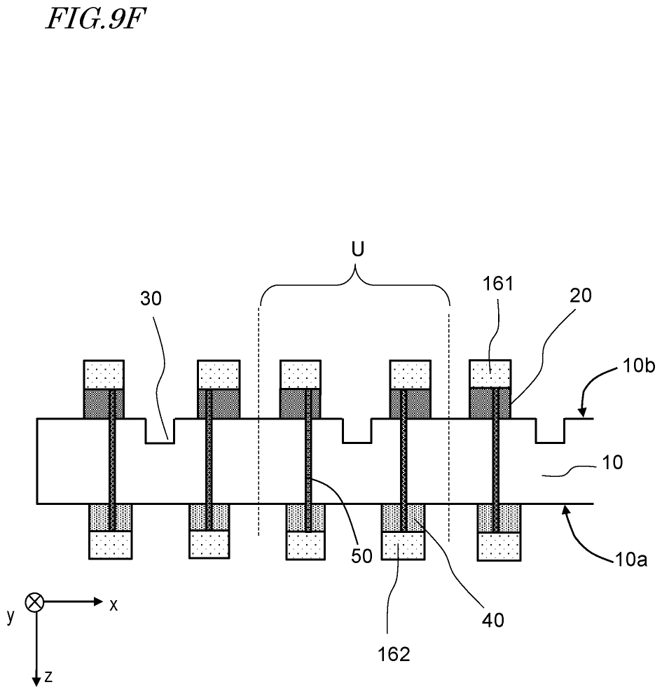

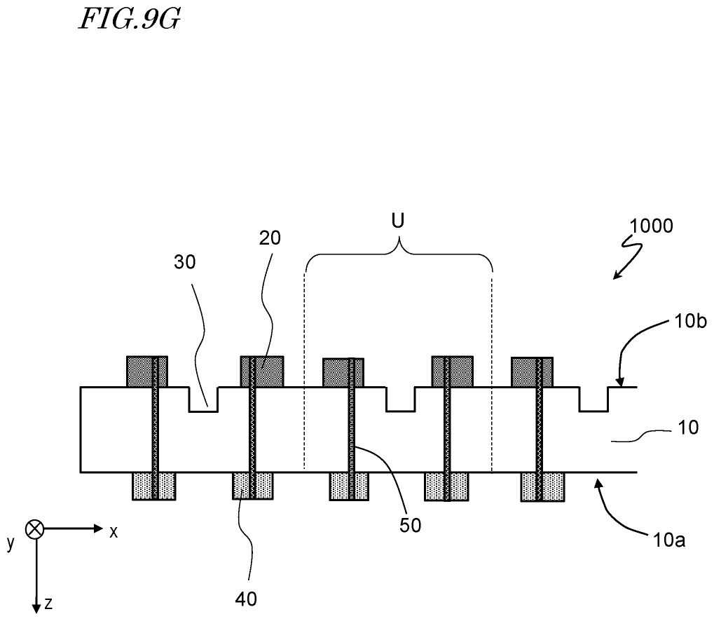

Hereinafter, a method of producing a substrate according to the present embodiment is described with reference to the drawings, based on an example of the method of producing the first substrate 1000 shown in FIG. 4A, FIG. 4B and FIG. 4C. FIG. 8A and FIG. 8B are, respectively, a top view and a cross-sectional view showing a part of a metal plate for use in production of the first substrate. FIG. 8C is a cross-sectional view showing a part of a pre-preg for use in production of the first substrate. FIG. 9A, FIG. 9B, FIG. 9C, FIG. 9D, FIG. 9E, FIG. 9F and FIG. 9G are each a cross-sectional view showing a step of the production method of the first substrate. For the sake of simplicity, FIG. 9A, FIG. 9B, FIG. 9C, FIG. 9D, FIG. 9E, FIG. 9F and FIG. 9G show only a part of the first substrate corresponding to two-unit regions U.

A method of producing a substrate for light emitting elements according to the present embodiment includes: (I) providing a sheet-like metal plate 120 and a pre-preg, the metal plate 120 having a first surface 120a and at least one raised portion (or ridge) 121 at the first surface 120a, the pre-preg including a plurality of fiber bundles and a resin; (II) binding together the first surface of the metal plate and the pre-preg; (III) forming a resin layer 10, which includes curing the pre-preg; (IV) forming a resist on the metal plate; (V) etching away the at least one raised portion of the metal plate; and (VI) removing the resist.

According to the present embodiment, after a first substrate 1000 that has a plurality of unit regions U has been produced by the above-described method, the first substrate 1000 may be divided or singulated into individual pieces corresponding to the unit regions U. This procedure can improve the productivity.

<Step (I)>

Providing a Metal Plate

A metal plate 120 shown in FIG. 8A and FIG. 8B is provided. Herein, a Cu plate having the thickness of, for example, 0.1 mm and the size of, for example, 1.2 m×1.0 m is provided, and etching (e.g., wet etching) is performed on a surface of the Cu plate, whereby a sheet-like metal plate 120 having at least one raised portion 121 is formed. The metal plate 120 has a first surface 120a and a second surface 120b located opposite to the first surface 120a. The first surface 120a preferably has a plurality of raised portions 121. The height of the raised portions 121 is, for example, 0.05 mm while the thickness of the metal plate 120 exclusive of the raised portions 121 is, for example, equal to or greater than 0.035 mm and equal to or smaller than 0.5 mm.

In this example, in a plan view, the plurality of raised portions 121, which are parallel to the y axis, are provided with intervals in the x direction across the first surface 120a. Each of the raised portions 121 may continuously extend from one end to the other end of the first surface 120a of the metal plate 120. The height of the raised portions 121 can be determined according to, for example, the depth of the groove portions 30 to be formed in the first substrate 1000 shown in FIG. 4B. The number, the arrangement, and the width in the x-axis direction in a plan view of the raised portions 121 can be determined according to the number, the arrangement, and the width in the x-axis direction in a plan view of the groove portions 30 to be formed in the first substrate 1000. The corner of the raised portion 121 may have a rounded shape (R shape). That is, modifying the shape of the raised portions 121 can improve the design flexibility of the groove portions 30.

Providing Pre-Preg

As shown in FIG. 8C, a pre-preg 110 is provided that includes a plurality of fiber bundles and a thermosetting resin in a semi-cured state (B-stage). The pre-preg 110 has a first surface 110a and a second surface 110b located opposite to the first surface 110a. Further, metal foil 140 is provided on the first surface 110a side of the pre-preg 110. The metal foil 140 is, for example, Cu foil (thickness: for example, equal to or greater than 0.1 mm and equal to or smaller than 0.2 mm). The metal foil 140 is used for formation of the upper electrically-conductive layers.

<Step (II)>

Next, the first surface 120a of the metal plate 120 and the pre-preg 110 are bound together. First, as shown in FIG. 9A, the second surfaces 120b of two metal plates 120 are set so as to face each other with a sheet-like supporter 130 interposed therebetween. In Step (II), two or more metal plates 120 are used so that the productivity of the first substrate 1000 can be improved. The supporter 130 can be a metal plate of stainless steel or the like, or a sheet of paper.

Then, as shown in FIG. 9B, the two metal plates 120 are stacked up with the supporter 130 interposed therebetween. Then, the second surface 110b of the pre-preg 110 is set so as to face the first surface 120a of the metal plate 120. In this example, the second surfaces 110b of the two pre-pregs 110 are set so as to face the first surfaces 120a of the two metal plates 120.

Then, as shown in FIG. 9C, the first surface 120a of the metal plate 120 and the second surface 110b of the pre-preg 110 are brought together. In this step, the metal foil 140 provided on the first surface 110a side of the pre-preg 110 is also compressed together, resulting in a multilayer body 150. In FIG. 9C, two multilayer bodies 150 are stacked up with the supporter 130 interposed therebetween. Note that, to further improve the productivity, three or more multilayer bodies 150 may be stacked up with supporters 130 interposed therebetween.

<Step (III)>

Thereafter, a resin layer 10 is formed by, for example, curing the pre-preg 110.

When a plurality of multilayer bodies 150 are stacked up, a plurality of pre-pregs 110 may be concurrently cured. The method of curing the pre-pregs 110 is not particularly limited. Herein, the multilayer bodies 150 are compressed in the stacking direction (z-axis direction) by, for example, pressing, while the multilayer bodies 150 are heated. The heating temperature can be set to, for example, a temperature equal to or higher than 130° C. and equal to or lower than 200° C., and the pressing pressure can be set to, for example, a pressure equal to or higher than 20 kg/cm² and equal to or lower than 60 kg/cm². Under such conditions, in the multilayer body 150, the semi-cured resin in the pre-preg 110 is once re-melted and then fully cured. In this way, the resin layer 10 is formed from the pre-preg 110. Because the pre-preg 110 deforms according to the shape of the first surface 120a of the metal plate 120, recesses 30E, which are to be the groove portions 30, are formed on the second surface 10b of the resin layer 10 in parts of the pre-preg 110 that are in contact with the raised portions 121 of the first surface 120a of the metal plate 120.

In this step, the fiber bundles in the pre-preg 110 can also deform according to the shape of the raised portions 121 of the first surface 120a of the metal plate 120. In the present embodiment, the resin layer 10 is formed such that a portion of at least one of the plurality of fiber bundles in the pre-preg 110 overlapping at least one groove portion 30 in a plan view is bent in the depth direction along the at least one groove portion 30. (See FIG. 3A.)

Thereafter, in the resin layer 10 resulting from the curing of the pre-preg 110, a plurality of through-holes are formed by, for example, laser or drilling. In this step, preferably, through-holes are also concurrently formed in either of the metal plate 120 or the metal foil 140. Thereafter, an electrical conductor 50 is provided in each of the through-holes. Note that the lateral surface of the through-holes may be plated with Cu as the electrical conductor 50. After the resin layer 10 has been formed, the multilayer body 150 including the resin layer 10 is separated off from the supporter 130 as shown in FIG. 9D.

<Step (IV)>

Subsequently, an etching resist (hereinafter, sometimes abbreviated to “resist”) is formed on the metal plate 120. As shown in FIG. 9E, in the multilayer body 150, a first resist 161 and a second resist 162 are formed on the first surface 120a of the metal plate 120 and the surface 140a of the metal foil 140, respectively. Herein, the etching resist is applied onto the first surface 120a of the metal plate 120 and the surface 140a of the metal foil 140 and subjected to exposure and development, whereby the first resist 161 and the second resist 162 are formed. The first resist 161 is provided in parts of the first surface 120a of the metal plate 120 that are not overlapping the groove portions 30 in a plan view. The first resist 161 has a pattern corresponding to the electrically-conductive layers 20 (FIG. 9F), and the second resist 162 has a pattern corresponding to the upper electrically-conductive layers 40 (FIG. 9F).

<Step (V)>

Next, at least one raised portion 121 of the metal plate 120 is etched away. As shown in FIG. 9F, etching is performed on the metal plate 120 using the first resist 161 as an etching mask, whereby parts of the metal plate 120 including the raised portions 121 are etched away. As a result, at least one groove portion 30 corresponding to the at least one raised portion 121 of the metal plate 120 is formed in the resin layer 10. Because the raised portions 121 of the metal plate 120 are removed and the groove portions 30 are formed after the pre-preg 110 has been cured, the shape of the groove portions 30 as designed can be precisely and easily realized. Further, by removing the raised portions 121, the metal plate 120 can be divided by the groove portions 30 into two or more parts, whereby the electrically-conductive layers 20 are formed.

Likewise, etching is performed on the metal foil 140 using the second resist 162 as an etching mask, whereby the metal foil 140 can be divided into the upper electrically-conductive layers 40.

<Step (VI)>

Thereafter, as shown in FIG. 9G, the first resist 161 and the second resist 162 are removed. In this way, the first substrate 1000 is produced.

Thereafter, the first substrate 1000 produced by the above-described method is divided or singulated into individual pieces corresponding to the unit regions U. By this singulation, the substrate 100 shown in FIG. 1A, FIG. 1B, FIG. 1C and FIG. 1D can be produced from each of the unit regions U. The first substrate 1000 may be divided into individual pieces after one or a plurality of light source sections 200 (FIG. 2B) or one or a plurality of light source sections 201 (FIG. 6) have been formed in each of the unit regions U on the first surface 10a of the first substrate 1000.

The method of singulation is not particularly limited. For example, the first substrate 1000 may be cut along the boundary between neighboring unit regions U by, for example, blade dicing or laser dicing. Although the unit regions U are rectangular in the example illustrated in FIG. 4A and FIG. 4B, the shape of the unit regions U is not limited to this example. The planar shape of the substrate 100 after the singulation may be circular, elliptical, or any other shape.

According to the above-described method, the first substrate 1000 and the substrate 100 can be produced, which have the groove portions 30 that can suppress a short circuit due to ion migration between electrically-conductive layers.

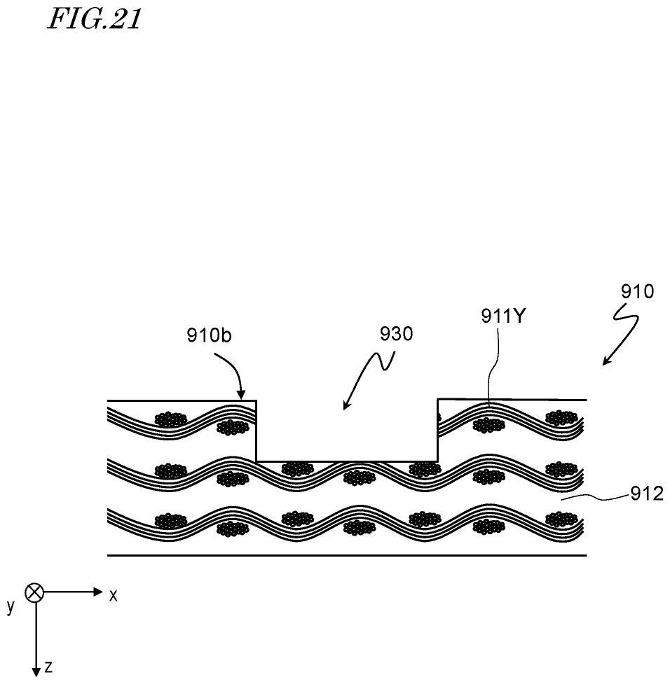

For example, when a groove portion is formed in a resin layer by a method of a reference example with the use of a dicer or laser, a fiber bundle 911Y located at a position shallower than the bottom of the groove portion 930 is cut off as shown in FIG. 21, and the cut sections of the fiber bundle 911Y are exposed at the surface of the groove portion 930 (in other words, at the surface 910b of the resin layer 910). Thus, there is a probability that the strength of the substrate will decrease. In contrast, in the present embodiment, the groove portion 30 is formed by deforming a semi-cured resin using the metal plate 120 that has the raised portions 121 (FIG. 8A and FIG. 8B). By this method, as shown in FIG. 3A, in the resin layer 10 of the present embodiment, the first fiber bundle 11Y located at a position shallower than the bottom P of the groove portion 30 is continuously provided so as to extend across the groove portion 30 inside the resin layer in a plan view. That is, the first fiber bundle 11Y is not cut off in forming the groove portion 30, and a part of the first fiber bundle 11Y is present between the groove portion 30 and the first surface 10a of the resin layer 10. Thus, the decrease in strength of the substrate 100 due to formation of the groove portion 30 can be suppressed.

Hereinafter, variant examples of the substrate and the light emitting device of the present embodiment are described. In the following description of the variant examples, the same features as those of the previously-described embodiments may not be described.

### Variant Example 1 of Substrate

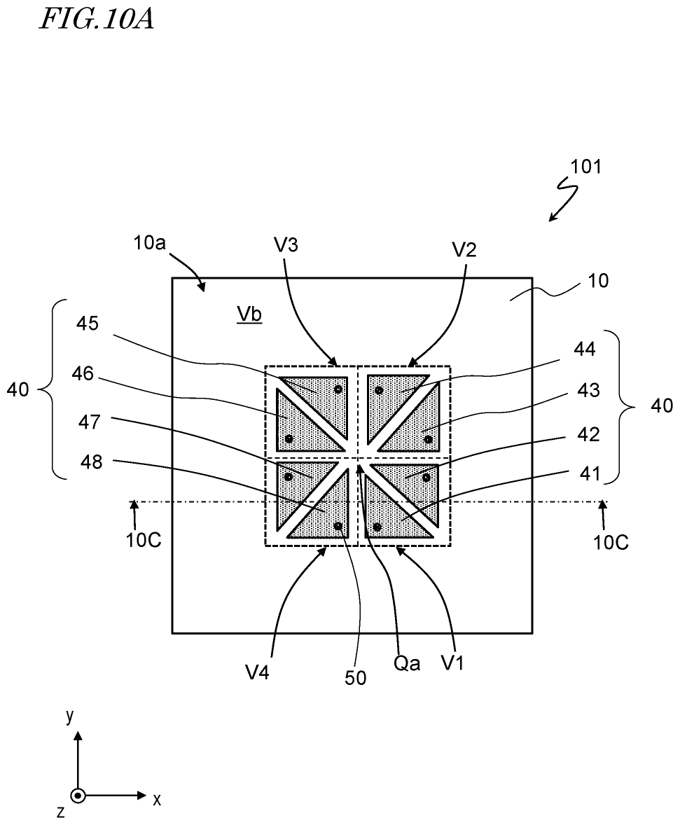

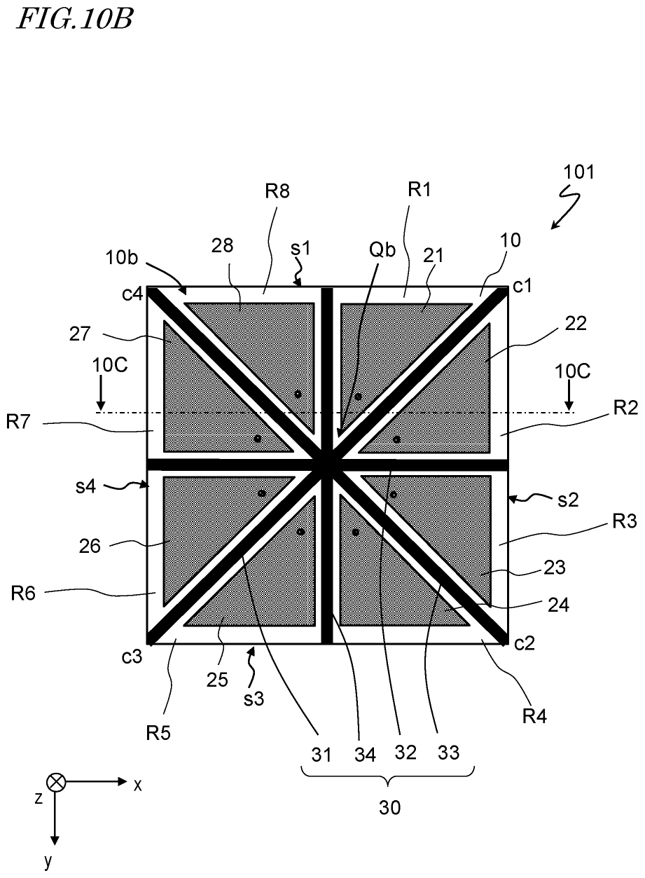

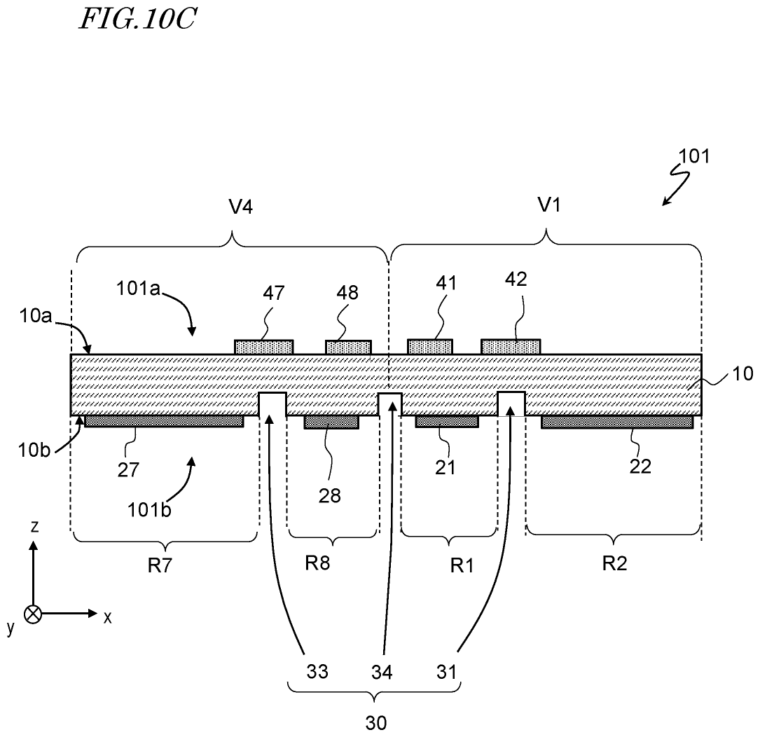

FIG. 10A and FIG. 10B are, respectively, a top view and a bottom view of a substrate 101 of Variant Example 1. FIG. 10C is a schematic cross-sectional view of the substrate 101 taken along line 10C-10C shown in FIG. 10A and FIG. 10B.

The substrate 101 includes a plurality of electrically-conductive layers 20 and a plurality of upper electrically-conductive layers 40. The plurality of electrically-conductive layers 20 include the first through eighth electrically-conductive layers 21, 22, 23, 24, 25, 26, 27 and 28. The plurality of upper electrically-conductive layers 40 include the first through eighth upper electrically-conductive layers 41, 42, 43, 44, 45, 46, 47 and 48.

As shown in FIG. 10B, the second surface 10b of the resin layer 10 is divided into eight planned electrically-conductive layer regions by groove portions 30, which include the first through fourth groove portions 31, 32, 33 and 34. The eight planned electrically-conductive layer regions are the first through eighth regions R1, R2, R3, R4, R5, R6, R7 and R8.

The first through fourth groove portions 31, 32, 33 and 34 linearly extend in a plan view and intersect at point Qb, which is the center of the second surface 10b. In this example, the second surface 10b of the resin layer 10 has a rectangular shape having four corners c1, c2, c3 and c4 and four sides s1, s2, s3 and s4, which is the same as the example shown in FIG. 1B. The first groove portion 31 extends from the corner c1 to the corner c3 of the second surface 10b. The third groove portion 33 extends from the corner c2 to the corner c4 of the second surface 10b. That is, the first groove portion 31 and the third groove portion 33 are located on the diagonals of the second surface 10b. The second groove portion 32 is substantially parallel to the x axis and divides the second surface 10b into the upper and lower parts (i.e., into two parts with respect to the y direction). The opposite ends of the second groove portion 32 may be in contact with the sides s2 and s4, respectively, of the second surface 10b. The fourth groove portion 34 is substantially parallel to the y axis and divides the second surface 10b into the left and right parts (i.e., into two parts with respect to the x direction). The opposite ends of the fourth groove portion 34 may be in contact with the sides s1 and s3, respectively, of the second surface 10b. In a plan view, the first through eighth regions R1, R2, R3, R4, R5, R6, R7 and R8 are right triangular regions surrounded by the groove portions 30 and the four sides of the second surface 10b of the substrate 101.

The first through eighth electrically-conductive layers 21, 22, 23, 24, 25, 26, 27 and 28 are located in the first through eighth regions R1, R2, R3, R4, R5, R6, R7 and R8, respectively. The first through eighth electrically-conductive layers 21, 22, 23, 24, 25, 26, 27 and 28 can have planar shapes that are substantially similar to the first through eighth regions R1, R2, R3, R4, R5, R6, R7 and R8, respectively. In this example, the planar shape of each of the first through eighth electrically-conductive layers 21, 22, 23, 24, 25, 26, 27 and 28 is a right triangle whose two sides are parallel to the x axis and the y axis.

As shown in FIG. 10A, the first surface 10a of the resin layer 10 includes a plurality of planned light source section regions and a peripheral region Vb that surrounds the planned light source section regions. The planned light source section regions mean regions on which light source sections including light emitting elements are to be placed. In this example, the plurality of planned light source section regions include four rectangular regions V1, V2, V3 and V4. Each side of the rectangular regions V1, V2, V3 and V4 is parallel to the x axis or the y axis. The regions V1, V2, V3 and V4 arrayed in two rows (x direction) and two columns (y direction). Herein, the regions V1, V2, V3 and V4 are the lower right region, the upper right region, the upper left region, and the lower left region with respect to point Qa. Point Qa is, for example, the center of the first surface 10a. Point Qa is the center of all the regions V1, V2, V3 and V4 and is preferably coincident with point Qb, which is the center of the second surface 10b, in a plan view.

The first through eighth upper electrically-conductive layers 41, 42, 43, 44, 45, 46, 47 and 48 are provided on the first surface 10a of the resin layer 10 so as to be spaced away from one another. The first through eighth upper electrically-conductive layers 41, 42, 43, 44, 45, 46, 47 and 48 are electrically connected to the first through eighth electrically-conductive layers 21, 22, 23, 24, 25, 26, 27 and 28, respectively, via the electrical conductors 50 in the through-holes formed in the resin layer 10. In this example, the shape of the first through eighth upper electrically-conductive layers 41, 42, 43, 44, 45, 46, 47 and 48 in a plan view is a right triangle whose two sides are parallel to the x axis and the y axis. In the region V1, the first upper electrically-conductive layer 41 and the second upper electrically-conductive layer 42 are provided. In the region V2, the third upper electrically-conductive layer 43 and the fourth upper electrically-conductive layer 44 are provided. In the region V3, the fifth upper electrically-conductive layer 45 and the sixth upper electrically-conductive layer 46 are provided. In the region V4, the seventh upper electrically-conductive layer 47 and the eighth upper electrically-conductive layer 48 are provided. In a plan view, the hypotenuses of the right triangles of two upper electrically-conductive layers 40 provided in each of the regions V1, V2, V3 and V4 face each other.

The substrate 101 can also be produced by the same method as that previously described with reference to FIG. 8A, FIG. 8B and FIG. 8C and FIG. 9A, FIG. 9B, FIG. 9C, FIG. 9D, FIG. 9E, FIG. 9F and FIG. 9G. In Step (I) illustrated in FIG. 8A and FIG. 8B, the metal plate 120 is used that has the plurality of raised portions 121 that linearly extend in a plan view, so that the groove portions 30 including the first through fourth groove portions 31, 32, 33 and 34 can be formed.

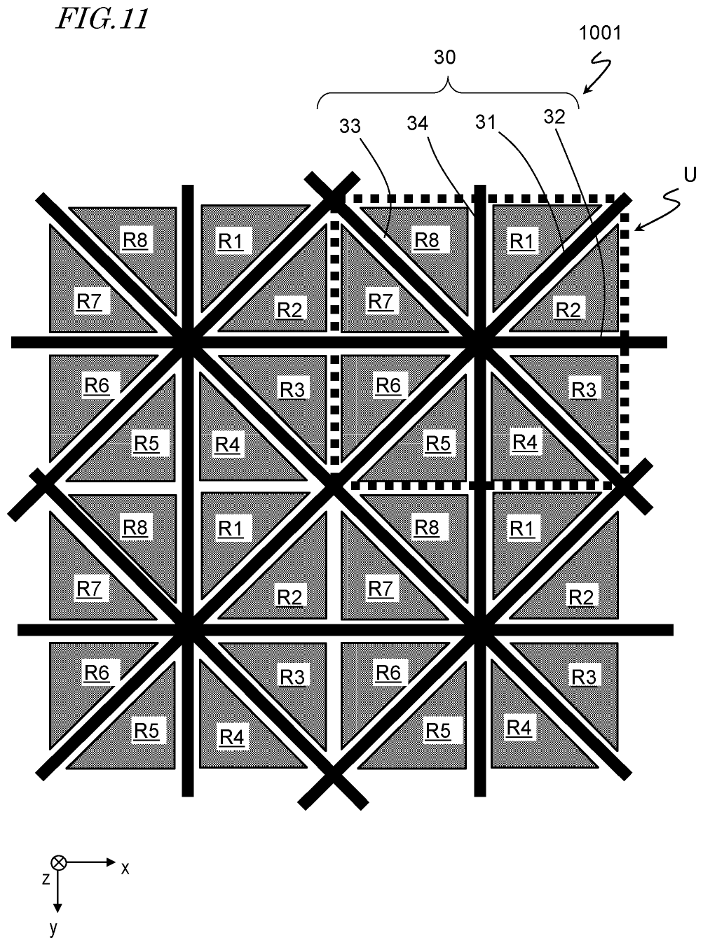

FIG. 11 is an enlarged bottom view showing a part of a first substrate 1001 according to the present embodiment. One of the unit regions U of the first substrate 1001 is the substrate 101. In the first substrate 1001, the first through fourth groove portions 31, 32, 33 and 34 in one of the unit regions U may be in communication with the groove portions 30 of a unit region U that is neighboring in the x direction, the y direction, or a diagonal direction.

### Variant Example 1 of Light Emitting Device

An example of a light emitting device that includes the substrate 101 of Variant Example 1 is described.

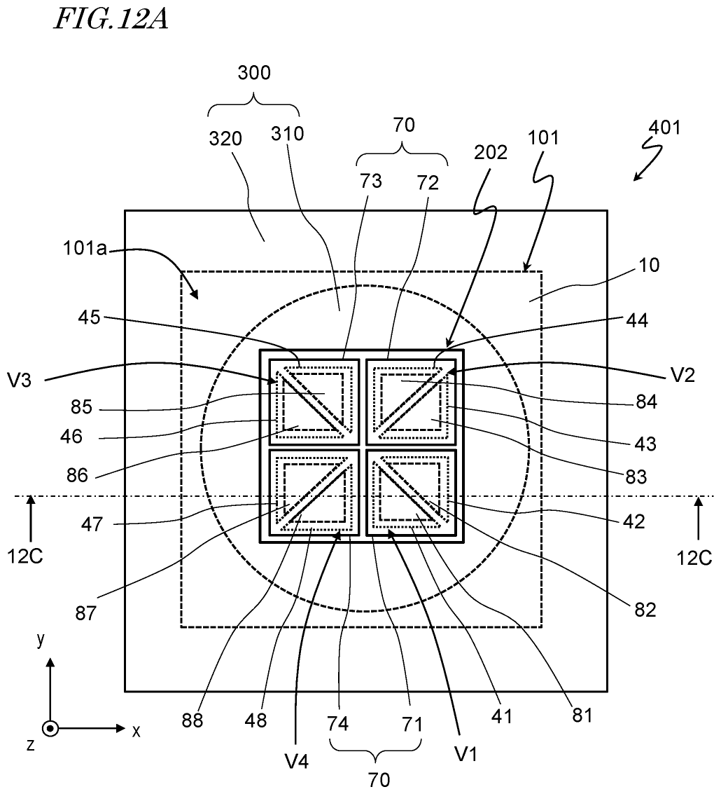

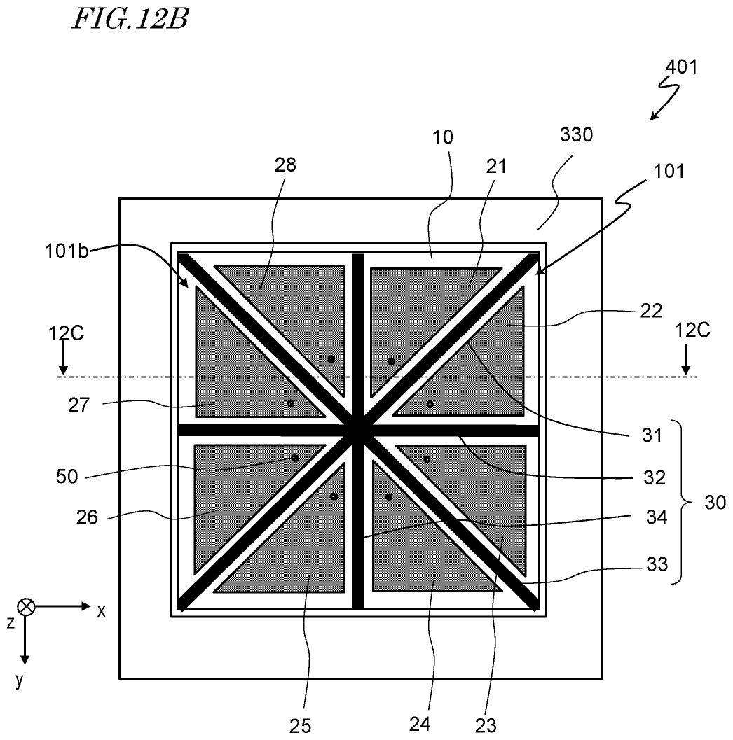

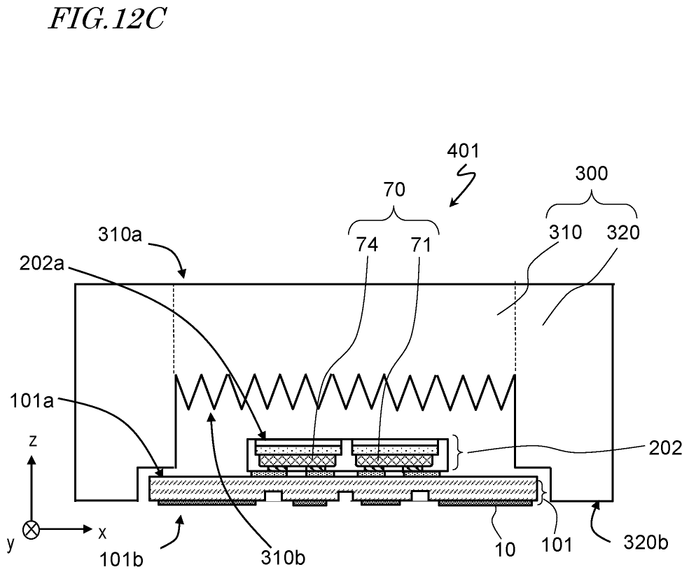

FIG. 12A is a schematic top view of a light emitting device 401. FIG. 12B is a bottom view of the light emitting device 401. FIG. 12C is a cross-sectional view of the light emitting device 401 taken along line 12C-12C shown in FIG. 12A.

The light emitting device 401 includes a substrate 101, a light source section 202, and a lens 300. The lens 300 has the configuration the same as or similar to that of the lens previously described with reference to FIG. 7A, FIG. 7B, FIG. 7C and FIG. 7D. The light source section 202 of the light emitting device 401 includes a plurality of light emitting elements 70. Hereinafter, the configuration of the light source section 202 is described in detail.

[Light Source Section 202]

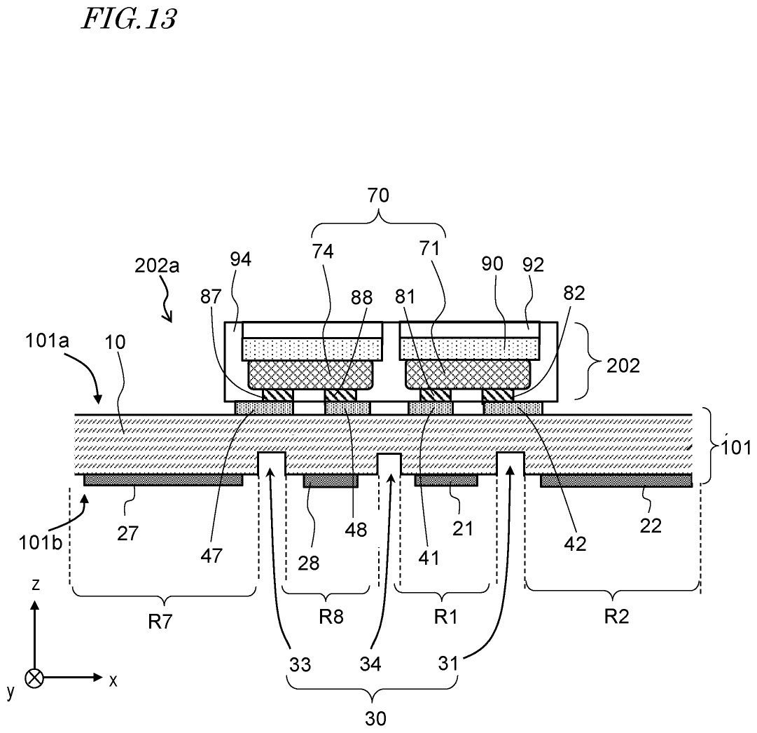

FIG. 13 is a diagram for illustrating the substrate 101 and the light source section 202. Specifically, FIG. 13 is a cross-sectional view of a structure equivalent to the light emitting device 401 shown in FIG. 12C from which the lens 300 has been removed.

The light source section 202 is provided on the upper surface 101a side of the substrate 101. The light source section 202 has a light emission surface 202a located opposite to the substrate 101. The light source section 202 includes a plurality of light emitting elements 70 that are two-dimensionally arrayed. The light source section 202 further includes a plurality of wavelength conversion layers 90, a plurality of diffusing layers 92, and a reflector 94.

As shown in FIG. 12A, each of the plurality of light emitting elements 70 is provided in a corresponding one of the planned light source section regions on the first surface 10a of the resin layer 10 of the substrate 101. In a plan view, each of the light emitting elements 70 is rectangular and is provided such that each side of the rectangle is parallel to the x axis or the y axis. Each of the light emitting elements 70 is provided so as to extend across the hypotenuses of neighboring two of the first through eighth upper electrically-conductive layers 41, 42, 43, 44, 45, 46, 47 and 48 in a plan view. The positive and negative electrodes of each of the light emitting elements 70 are present above the two neighboring upper electrically-conductive layers. The positive and negative electrodes of the light emitting elements 70 have a triangular (herein, right triangular) planar shape.

In this example, the plurality of light emitting elements 70 are the first through fourth light emitting elements 71, 72, 73 and 74. The first through fourth light emitting elements 71, 72, 73 and 74 are provided in the regions V1, V2, V3 and V4, respectively, on the first surface 10a of the resin layer 10. The electrodes 81, 82 of the first light emitting element 71 are electrically connected to the first upper electrically-conductive layer 41 and the second upper electrically-conductive layer 42 via, for example, a bonding material such as solder. Likewise, the electrodes 83, 84, 85, 86, 87 and 88 of the second through fourth light emitting elements 72, 73 and 74 are electrically connected to the third through eighth upper electrically-conductive layers 43, 44, 45, 46, 47 and 48, respectively.

As shown in FIG. 13, the plurality of wavelength conversion layers 90 are provided on the light exit surfaces 70a of corresponding ones of the light emitting elements 70 and are separated from one another. In this example, each of the light emitting elements 70 includes a wavelength conversion layer 90, although a common wavelength conversion layer may be provided for the plurality of light emitting elements 70.

Each of the plurality of diffusing layers 92 is provided on the upper surface of a corresponding one of the wavelength conversion layers 90. The plurality of diffusing layers 92 are separated from one another. In this example, each of the light emitting elements 70 includes a diffusing layer 92, although a common diffusing layer 92 may be provided for the plurality of light emitting elements 70.

The reflector 94 encapsulates, and integrally holds, the first through fourth light emitting elements 71, 72, 73 and 74. The reflector 94 may be provided for each of the light emitting elements 70. In this case, the reflectors 94 may be separated from one another. When a reflector 94 is provided between two neighboring light emitting elements 70, transmission of light between the light emitting elements 70 can be suppressed, so that unevenness in emission color can be reduced. Further, in the lighting operation where the plurality of light emitting elements 70 are controlled independently of one another, the contrast between lit light emitting elements and unlit light emitting elements can be improved.

### Variant Example 2 of Substrate

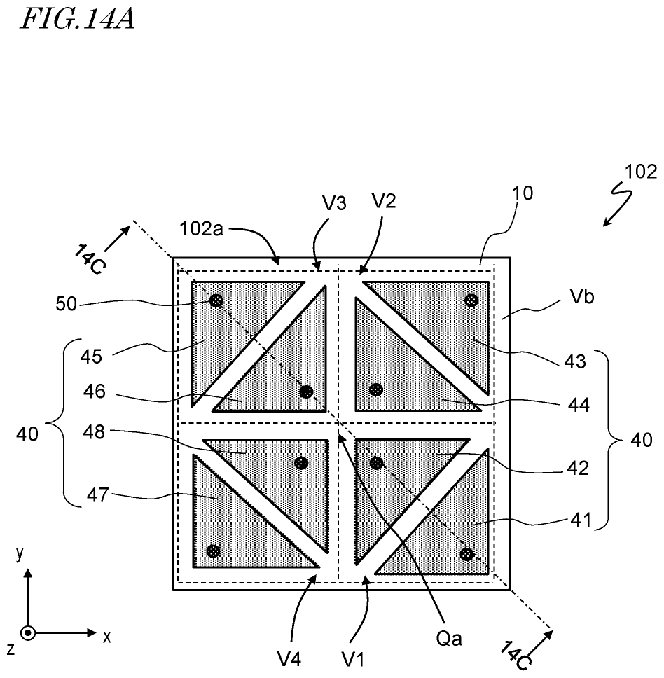

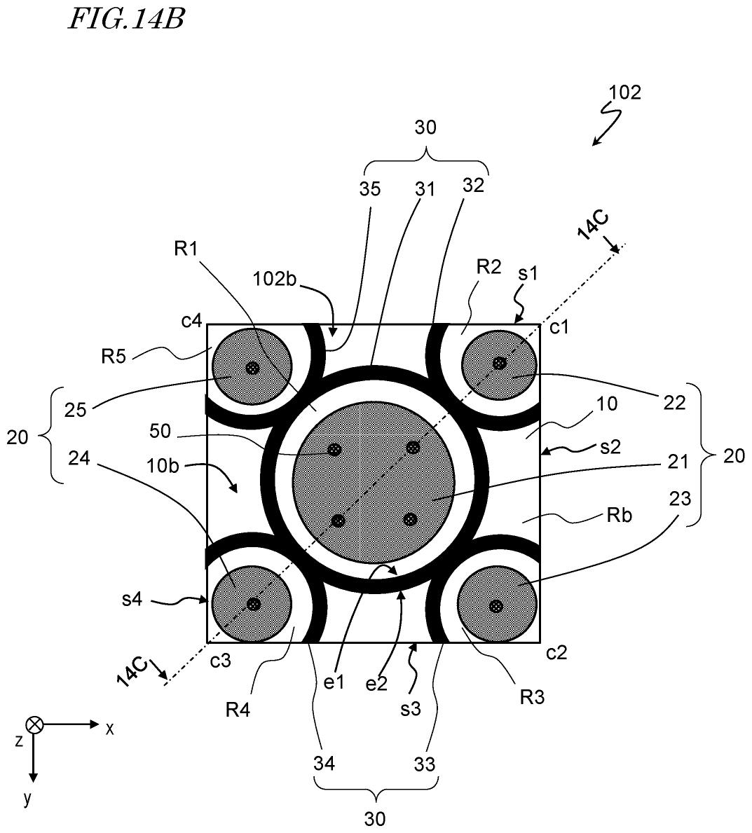

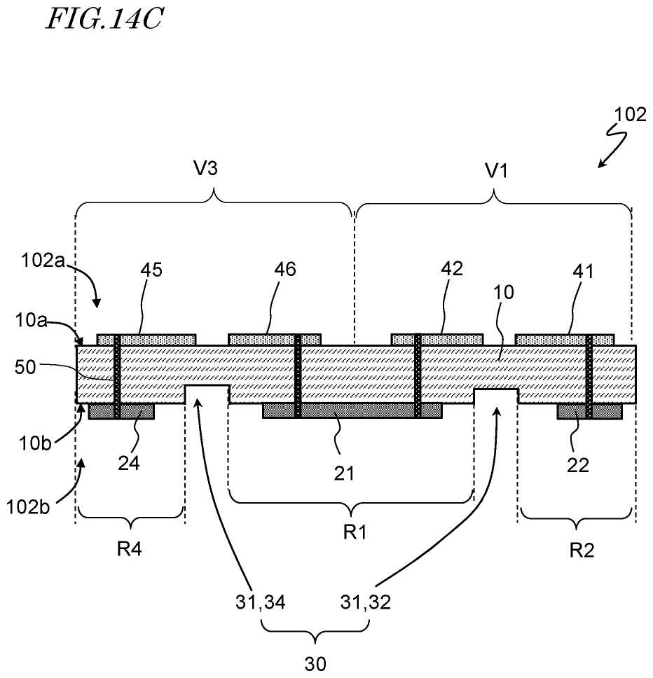

FIG. 14A and FIG. 14B are, respectively, a top view and a bottom view of a substrate 102 of Variant Example 2. FIG. 14C is a cross-sectional view of the substrate 102 taken along line 14C-14C shown in FIG. 14A and FIG. 14B.

The substrate 102 includes a plurality of electrically-conductive layers 20, which include the first through fifth electrically-conductive layers 21, 22, 23, 24 and 25, and a plurality of upper electrically-conductive layers 40, which include the first through eighth upper electrically-conductive layers 41, 42, 43, 44, 45, 46, 47 and 48.

As shown in FIG. 14B, the second surface 10b of the resin layer 10 has groove portions 30 and a plurality of planned electrically-conductive layer regions. The groove portions 30 include an annular groove portion or a groove portion having an arc portion in a plan view. In this example, the groove portions 30 include the first through fifth groove portions 31, 32, 33, 34 and 35, which are annular or have an arc portion in a plan view. The plurality of planned electrically-conductive layer regions are the first through fifth regions R1, R2, R3, R4 and R5. In a plan view, the first groove portion 31 is annular, the first region R1 is a region surrounded by the first groove portion 31, and the second through fifth regions R2, R3, R4 and R5 are located on the side opposite to the first region R1 with respect to the first groove portion 31 interposed therebetween.

In a plan view, the first groove portion 31 is annular. The first groove portion 31 has, in a plan view, the first annular edge e1 and the second annular edge e2 that is on the outer side of the first edge e1 and that is opposite to the first edge e1. In this example, the first groove portion 31 is in the shape of a substantially circular annulus in a plan view. In the present specification, the term “annular” refers to a ring in the shape of a circle, an ellipse, or a polygon with rounded corners in a plan view. An annular groove portion may include an arc portion that is a part of a circle or ellipse, or may include a linear portion, so long as the annular groove portion has a ring-like shape in a plan view.

The second through fifth groove portions 32, 33, 34 and 35 include, in a plan view, a portion overlapping the first annular groove portion 31 and are located on the second edge e2 side of the first groove portion 31. In other words, each of the second through fifth groove portions 32, 33, 34 and 35 and the first annular groove portion 31 share a part of the groove portions 30. In this example, the second surface 10b has a rectangular shape, which has four corners c1, c2, c3 and c4 and four sides s1, s2, s3 and s4. The second groove portion 32 has an arc portion concaved toward the corner c1 in a plan view. Likewise, the third through fifth groove portions 33, 34 and 35 have arc portions concaved toward the corners c2, c3 and c4, respectively, in a plan view.

The second surface 10b is divided by the above-described first through fifth groove portions 31, 32, 33, 34 and 35 into the first through fifth regions R1, R2, R3, R4 and R5 and the outer region Rb.

The first region R1 refers to a region surrounded by the first groove portion 31. The second through fifth regions R2, R3, R4 and R5 are located on the outer side of the first groove portion 31. In the illustrated example, each of the second through fifth regions R2, R3, R4 and R5 is located between the first region R1 and a corresponding one of the four corners c1, c2, c3 and c4. The second region R2 refers to a region surrounded by the second groove portion 32 in the shape of an arc and two sides s1, s2 that form the corner c1 of the resin layer 10. Likewise, the third through fifth regions R3, R4 and R5 refer to regions surrounded by the third through fifth groove portions 33, 34 and 35 and two sides that form corresponding ones of the corners c2, c3 and c4.

The outer region Rb is located on the outer side of the planned electrically-conductive layer regions and refers to a region on which the electrically-conductive layers 20 are not to be provided. The outer region Rb may be a single continuous region or may include a plurality of separate regions. The outer region Rb is separated from the planned electrically-conductive layer regions by the groove portions 30. In this example, the outer region Rb is located outside the first region R1, at a position between two neighboring planned electrically-conductive layer regions. Between the two-neighboring planned electrically-conductive layer regions and the outer region Rb located therebetween, the groove portions 30 are provided. In this example, in a plan view, in a part of the second surface 10b of the resin layer 10 that is on the side opposite to the first region R1 with respect to the first groove portion 31 interposed therebetween, the second groove portion 32 is located between the second region R2 and the outer region Rb positioned outward of the second region R2. Further, the second groove portion 32 includes a portion elongated in the shape of an arc or annulus. Likewise, the third groove portion 33 is located between the third region R3 and the outer region Rb. The fourth groove portion 34 is located between the fourth region R4 and the outer region Rb. The fifth groove portion 35 is located between the fifth region R5 and the outer region Rb.

The first through fifth electrically-conductive layers 21, 22, 23, 24 and 25 are provided in the first through fifth regions R1, R2, R3, R4 and R5, respectively. The first electrically-conductive layer 21 is located on the inner side of the first edge e1 of the first groove portion 31 so as to be spaced away from the first edge e1. The second through fifth electrically-conductive layers 22, 23, 24 and 25 are located on the inner side of the edges of the second through fifth groove portions 32, 33, 34 and 35, respectively, that are in the shape of an arc so as to be spaced away from the edges. In this example, the first through fifth electrically-conductive layers 21, 22, 23, 24 and 25 have a substantially circular planar shape. In a plan view, the second through fifth electrically-conductive layers 22, 23, 24 and 25 may have a smaller area than the first electrically-conductive layer 21.

That is, the second surface 10b of the resin layer 10 has a rectangular shape, which has four corners c1, c2, c3 and c4. In a plan view, the second surface 10b of the resin layer 10 further includes the second region R2, the third region R3, the fourth region R4 and the fifth region R5, and the outer region Rb exclusive of the second region R2, the third region R3, the fourth region R4 and the fifth region R5. The second region R2, the third region R3, the fourth region R4 and the fifth region R5 are located between the first groove portion 31 and the four corners c1, c2, c3 and c4, respectively. The substrate 100 for light emitting elements further includes the third electrically-conductive layer 23, the fourth electrically-conductive layer 24 and the fifth electrically-conductive layer 25 provided in the third region R3, the fourth region R4 and the fifth region R5, respectively. In a plan view, at least one groove portion 30 further includes the second groove portion 32 located between the second region R2 and the outer region Rb, the third groove portion 33 located between the third region R3 and the outer region Rb, the fourth groove portion 34 located between the fourth region R4 and the outer region Rb, and the fifth groove portion 35 located between the fifth region R5 and the outer region Rb. In a plan view, each of the second groove portion 32, the third groove portion 33, the fourth groove portion 34 and the fifth groove portion 35 has an arc portion that is in contact with the first groove portion 31.

As shown in FIG. 14A, the first surface 10a of the resin layer 10 includes a plurality of planned light source section regions and a peripheral region Vb that surrounds the planned light source section regions. In this example, the plurality of planned light source section regions are four rectangular regions V1, V2, V3 and V4. Each side of the rectangular regions V1, V2, V3 and V4 is parallel to the x axis or the y axis. Herein, the regions V1, V2, V3 and V4 are the lower right region, the upper right region, the upper left region, and the lower left region with respect to point Qa. Point Qa is the center of all the regions V1, V2, V3 and V4 and is, for example, the center of the first surface 10a.

The first through eighth upper electrically-conductive layers 41, 42, 43, 44, 45, 46, 47 and 48 are provided across the first surface 10a of the resin layer 10 so as to be spaced away from one another. In this example, each of the first through eighth upper electrically-conductive layers 41, 42, 43, 44, 45, 46, 47 and 48 has a right triangular shape whose two sides are parallel to the x axis and the y axis. In the region V1, the first upper electrically-conductive layer 41 and the second upper electrically-conductive layer 42 are provided. In the region V2, the third upper electrically-conductive layer 43 and the fourth upper electrically-conductive layer 44 are provided. In the region V3, the fifth upper electrically-conductive layer 45 and the sixth upper electrically-conductive layer 46 are provided. In the region V4, the seventh upper electrically-conductive layer 47 and the eighth upper electrically-conductive layer 48 are provided. In a plan view, two upper electrically-conductive layers 40 provided in each region V are provided such that the hypotenuses of the right triangles face each other. In a plan view, in each of the regions V1, V2, V3 and V4, the right angle vertex of the right triangle of one of the upper electrically-conductive layers 40 (herein, the second upper electrically-conductive layer 42, the fourth upper electrically-conductive layer 44, the sixth upper electrically-conductive layer 46, or the eighth upper electrically-conductive layer 48) is located near point Qa of the first surface 10a, while the right angle vertex of the right triangle of the other upper electrically-conductive layer 40 (herein, the first upper electrically-conductive layer 41, the third upper electrically-conductive layer 43, the fifth upper electrically-conductive layer 45, or the seventh upper electrically-conductive layer 47) is located near a corresponding one of the four corners of the first surface 10a.

The second upper electrically-conductive layer 42, the fourth upper electrically-conductive layer 44, the sixth upper electrically-conductive layer 46 and the eighth upper electrically-conductive layer 48 are each electrically connected to the first electrically-conductive layer 21 via the electrical conductor 50 in the through-hole formed in the resin layer 10. Meanwhile, the first upper electrically-conductive layer 41, the third upper electrically-conductive layer 43, the fifth upper electrically-conductive layer 45 and the seventh upper electrically-conductive layer 47, which are located near the four corners of the first surface 10a, are electrically connected to the second through fifth electrically-conductive layers 22, 23, 24 and 25, respectively, via the electrical conductors 50 in the through-holes formed in the resin layer 10.

The substrate 102 can also be produced by the same method as that previously described with reference to FIG. 8A, FIG. 8B and FIG. 8C and FIG. 9A, FIG. 9B, FIG. 9C, FIG. 9D, FIG. 9E, FIG. 9F and FIG. 9G. In Step (I) illustrated in FIG. 8A and FIG. 8B, the metal plate 120 is used that has a raised portion elongated in the shape of an arc or annulus in a plan view, so that the groove portions 30 including an annular or arc portion can be formed. A collective first substrate may be produced by the above-described method and thereafter divided into individual pieces corresponding to the unit regions.

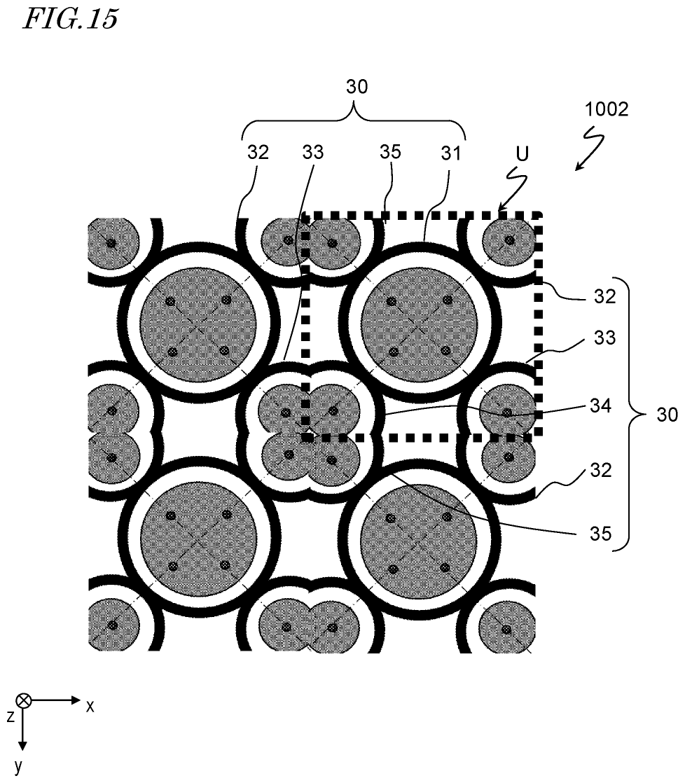

FIG. 15 is an enlarged bottom view showing a part of a collective first substrate 1002 according to the present embodiment. In the first substrate 1002, the second through fifth arc-shaped groove portions 32, 33, 34 and 35 of one of the unit regions U may be in communication with the arc-shaped groove portions of a neighboring unit region that is adjacent in the x direction or the y direction. The second through fifth groove portions 32, 33, 34 and 35 of neighboring unit regions U may be in communication with one another such that annular groove portions can be formed.

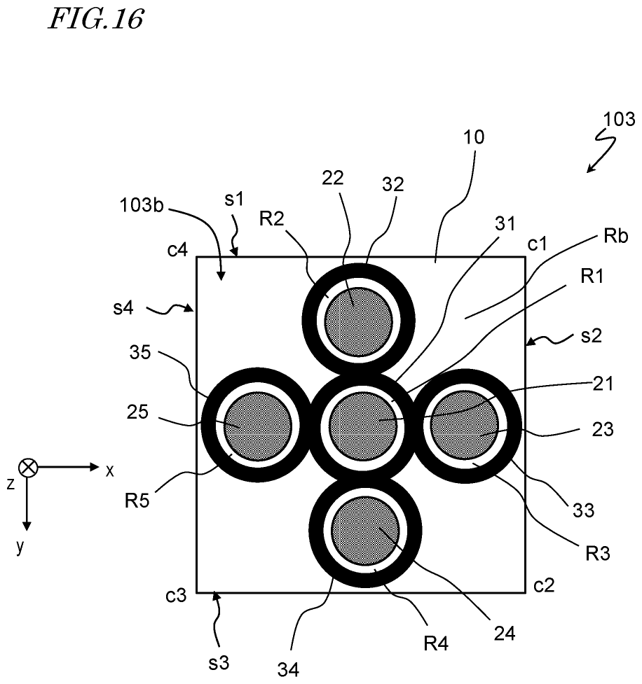

FIG. 16 is a bottom view showing an alternative substrate 103 according to Variant Example 2. In the example illustrated in FIG. 16, the second surface 10b of the resin layer 10 has a first annular groove portion 31, and second through fifth groove portions 32, 33, 34 and 35 that are located on the outer side of the first groove portion 31 in a plan view. In a plan view, the second through fifth groove portions 32, 33, 34 and 35 are each an annular groove portion and are located in the −y direction, the +x direction, the +y direction and the −x direction, respectively, relative to the first groove portion 31. Each of the second through fifth groove portions 32, 33, 34 and 35 may be in contact with the first groove portion 31.

The second surface 10b of the resin layer 10 includes the first through fifth regions R1, R2, R3, R4 and R5, which are the planned electrically-conductive layer regions, and an outer region Rb positioned outward of the planned electrically-conductive layer regions. The first through fifth regions R1, R2, R3, R4 and R5 refer to regions surrounded by the first through fifth groove portions 31, 32, 33, 34 and 35, respectively. The areas of the first through fifth regions R1, R2, R3, R4 and R5 may be substantially equal or may be different from one another. The outer region Rb refers to a region located outside the first through fifth regions R1, R2, R3, R4 and R5. In this example, the outer region Rb is a single continuous region.

The first through fifth electrically-conductive layers 21, 22, 23, 24 and 25 are provided in the first through fifth regions R1, R2, R3, R4 and R5, respectively. The planar shapes of the first through fifth electrically-conductive layers 21, 22, 23, 24 and 25 may be similar to, or different from, the planar shapes of the first through fifth regions R1, R2, R3, R4 and R5, respectively.

In this variant example, the number, shape, and arrangement of the groove portions 30, the planned electrically-conductive layer regions and the electrically-conductive layers 20 are not limited to the examples illustrated in the drawings. The substrates 102 and 103 shown in FIG. 14A, FIG. 14B and FIG. 14C and FIG. 16 have five planned electrically-conductive layer regions and five electrically-conductive layers 20, although the number of planned electrically-conductive layer regions and the number of electrically-conductive layers 20 may be two or more.

### Variant Example 3 of Substrate

Hereinafter, as Variant Example 3, another arrangement example of the groove portions and the planned electrically-conductive layer regions in the second surface of the resin layer is described.

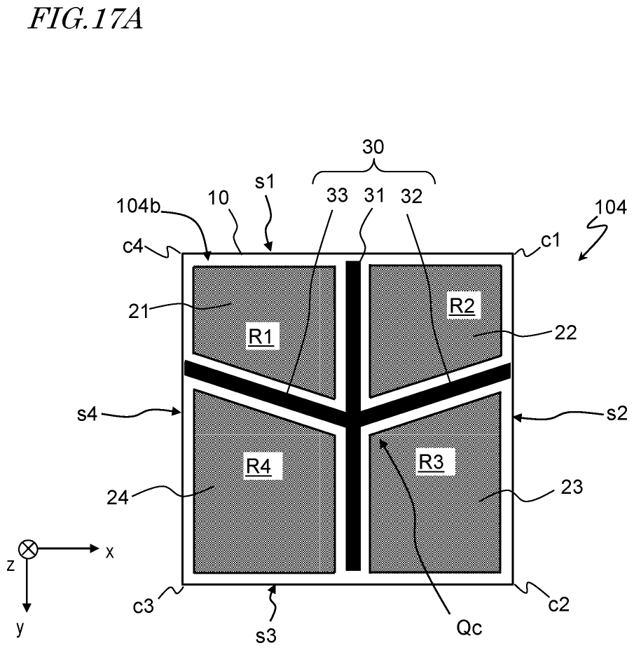

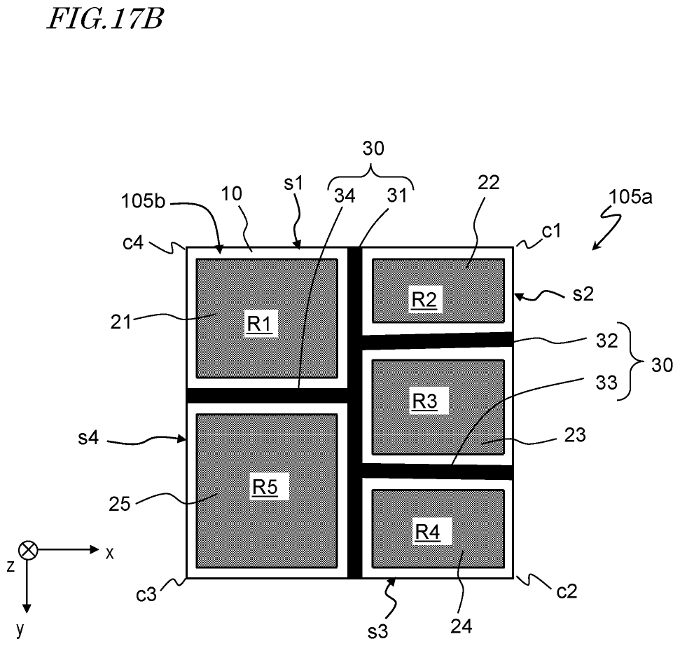

FIG. 17A is a bottom view illustrating a substrate 104 of Variant Example 3.

In the substrate 104, the planar shape of the second surface 10b of the resin layer 10 is a rectangular shape having four corners c1, c2, c3 and c4 and four sides s1, s2, s3 and s4, which is the same as the example shown in FIG. 1B. The second surface 10b has groove portions 30 that include portions extending linearly in different directions in a plan view. The second surface 10b is divided by the groove portions 30 into a plurality of planned electrically-conductive layer regions.

In the example illustrated in the drawing, the groove portions 30 include the first groove portion 31 that extends so as to divide the second surface 10b into left and right parts (x direction), the second groove portion 32 that extends so as to divide the region on the right side (+x side) of the first groove portion 31 into upper and lower parts (y direction), and the third groove portion 33 that extends so as to divide the region on the left side (−x side) of the first groove portion 31 into upper and lower parts (y direction). The second groove portion 32 and the third groove portion 33 are linear groove portions extending in directions intersecting each other. The second groove portion 32 is in communication with the first groove portion 31, and the end on the +x direction side of the second groove portion 32 is in contact with the periphery (side s2) of the second surface 10b. Likewise, the third groove portion 33 is in communication with the first groove portion 31, and the end on the −x direction side of the third groove portion 33 is in contact with the periphery (side s4) of the second surface 10b. In a plan view, the first groove portion 31, the second groove portion 32 and the third groove portion 33 meet at a single point Qc.

The second surface 10b is divided by the above-described groove portions 30 into the first through fourth regions R1, R2, R3 and R4. In the first through fourth regions R1, R2, R3 and R4, the first through fourth electrically-conductive layers 21, 22, 23 and 24 are respectively provided.

In this variant example, at least one groove portion 30 may include a groove portion that has, in a plan view, the first position at the periphery of the second surface 10b of the resin layer 10, the second position that is present within the second surface 10b, and a linear portion extending linearly from the first position to the second position. The “first position” and the “second position” of the groove portion may be the ends of the groove portion. In the example illustrated in the drawing, the second groove portion 32 and the third groove portion 33 each include the first position at the periphery of the second surface 10b, the second position including point Qc that is positioned inner side of the second surface 10b, and a linear portion extending linearly from the first position to the second position.

According to the method previously described with reference to FIG. 8A, FIG. 8B and FIG. 8C and FIG. 9A, FIG. 9B, FIG. 9C, FIG. 9D, FIG. 9E, FIG. 9F and FIG. 9G, by modifying the shape of the raised portions 121 of the metal plate 120, groove portions can be more easily formed so as to meet within the second surface 10b (herein, intersect at point Qb), for example, as do the second groove portion 32 and the third groove portion 33 shown in FIG. 17A.

FIG. 17B is a bottom view illustrating an alternative substrate 105a of Variant Example 3.

In the substrate 105a, the groove portions 30 include a linear groove portion extending parallel to the y axis and linear groove portions extending parallel to the x axis. In this example, in a plan view, the groove portions 30 include the first groove portion 31 that extends along the y axis so as to divide the second surface 10b in the x direction, the second groove portion 32 and the third groove portion 33 that divide the region on the right side (+x side) of the first groove portion 31 in the y direction into three parts, and the fourth groove portion 34 that divides the region on the left side (−x side) of the first groove portion 31 in the y direction. The second through fourth groove portions 32, 33 and 34 may be linear groove portions extending parallel to the x axis in a plan view. Each of the second groove portion 32 and the third groove portion 33 may be in communication with the first groove portion 31 at one end on the −x direction side, while the other end on the +x direction side may be in contact with the periphery (side s2) of the second surface 10b. The fourth groove portion 34 may be in communication with the first groove portion 31 at one end on the +x direction side, while the other end on the −x direction side may be in contact with the periphery (side s4) of the second surface 10b. The second through fourth groove portions 32, 33 and 34 each have the first position at the periphery of the second surface 10b, the second position that is positioned inner side of the second surface 10b (herein, the position at which the groove portion connects with the first groove portion 31), and a linear portion extending linearly from the first position to the second position.

The second surface 10b is divided by the above-described groove portions 30 into the first through fifth regions R1, R2, R3, R4 and R5. In the first through fifth regions R1, R2, R3, R4 and R5, the first through fifth electrically-conductive layers 21, 22, 23, 24 and 25 are respectively provided.

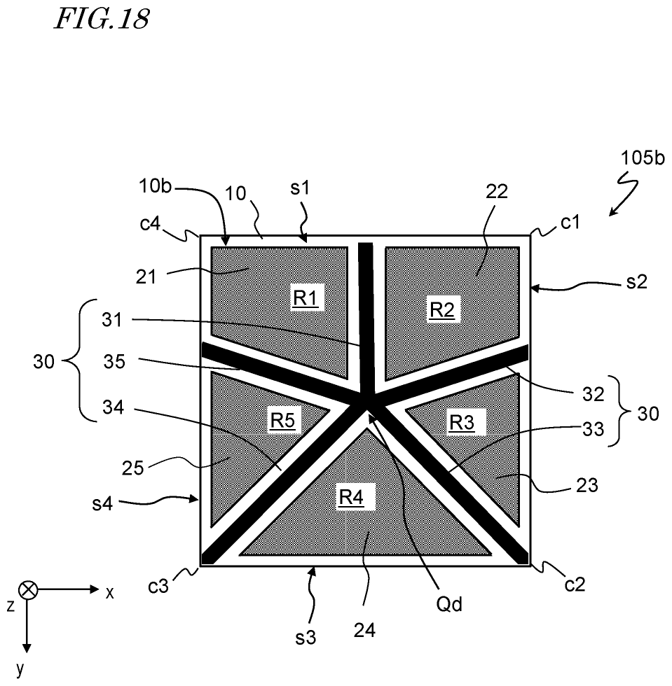

Also in this variant example, the number, planar shape, and arrangement of the groove portions and the planned electrically-conductive layer regions are not limited to the examples illustrated in the drawings. For example, as shown in FIG. 18, in the substrate 105b, the second surface 10b of the resin layer 10 has the first through fifth groove portions 31, 32, 33, 34 and 35 radially extending from point Qd, which is positioned inner side of the second surface 10b, toward the periphery of the second surface 10b in a plan view.

### Variant Example 4 of Substrate

Other examples of the cross-sectional shape of the groove portions are described. By appropriately changing the cross-sectional shape of the raised portions 121 of the metal plate 120 (see FIG. 8A and FIG. 8B), the groove portions 30 formed in the resin layer 10 can have various shapes. Therefore, the cross-sectional shape of the groove portions 30 can be set with high flexibility. For example, the width of the groove portions 30 may be varied in the depth direction (z direction). For example, the width w of the opening of the groove portions 30 may be greater than the width of the bottom P of the groove portions 30. The depth of a groove portion may be varied in the width direction (±x direction) of the groove portion. A single continuous groove portion may include a plurality of portions that have different cross-sectional shapes, or that have different opening widths w.

Hereinafter, variant examples of the shape of the groove portions 30 provided in the resin layer 10 are described. Note that the shapes of the groove portions in this variant example are applicable to some or all of the groove portions in the substrates of the present embodiment (for example, the previously-described substrates 101, 102, 103, 104, 105a and 105b).

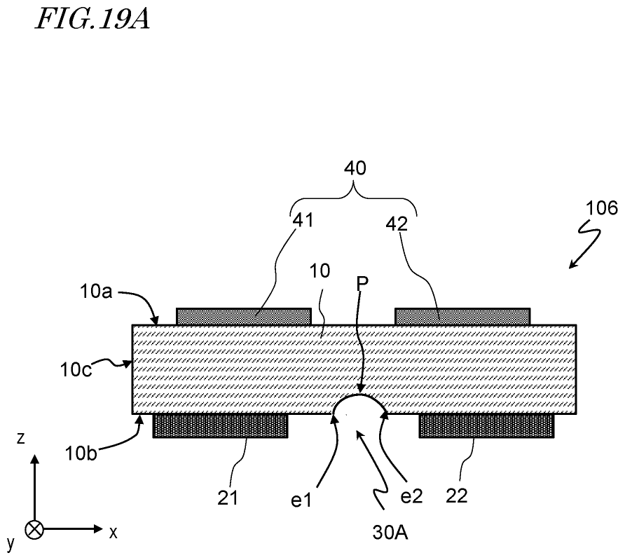

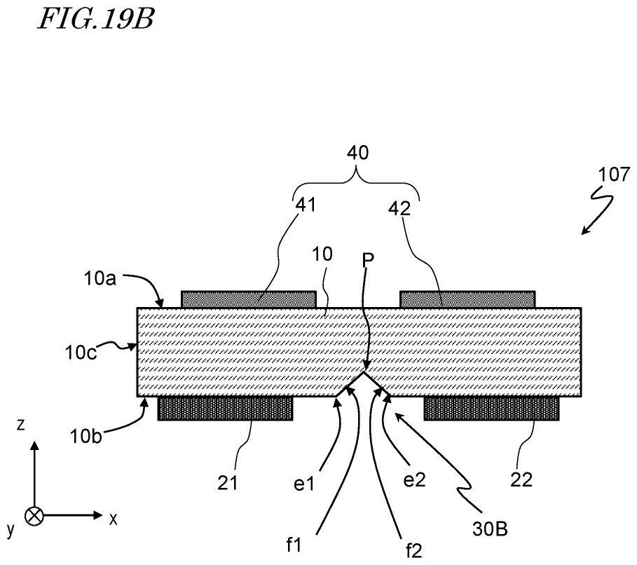

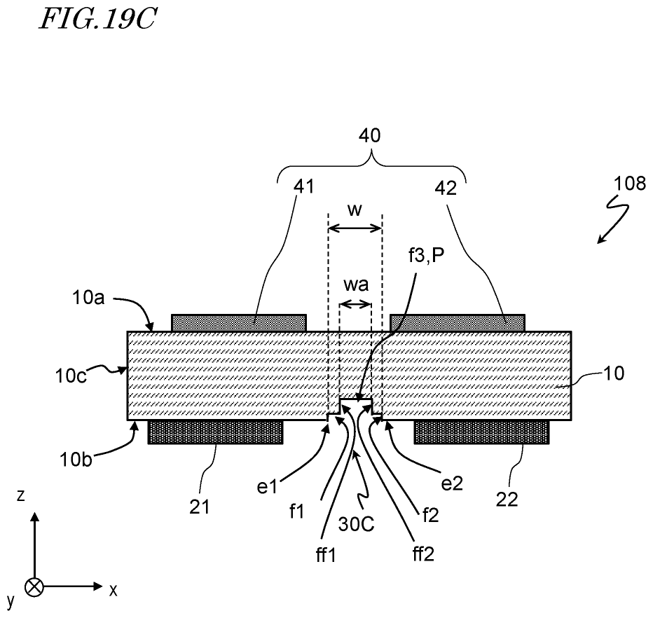

FIG. 19A, FIG. 19B and FIG. 19C are cross-sectional views of the substrates 106, 107 and 108, respectively, of Variant Example 4, which show the groove portions 30A, 30B and 30C and the first electrically-conductive layer 21 and the second electrically-conductive layer 22 provided on the opposite sides of the groove portion.

In the substrate 106 shown in FIG. 19A, the cross-sectional shape of the groove portion 30A includes an arc that is a part of a circle or ellipse. In this example, in a cross-sectional view, the bottom of the groove portion 30A is in the shape of a concaved arc. The groove portion 30A includes the bottom P that is the deepest point in a cross-sectional view.

In the substrate 107 shown in FIG. 19B, the cross-sectional shape of the groove portion 30B is a V shape. In this example, in a cross-sectional view, the groove portion 30B has a bottom P that is the deepest point, a lateral surface f1 located between the bottom P and the first edge e1, and a lateral surface f2 located between the bottom P and the second edge e2. In a cross-sectional view, the angle between the lateral surface f1 and the lateral surface f2 may be, for example, about 90°. That is, the groove portion 30B may be a part of a rectangle.

In the substrate 108 shown in FIG. 19C, the cross-sectional shape of the groove portion 30C has a bottom surface f3 whose width is smaller than the width of the opening. In a cross-sectional view, the groove portion 30C includes the bottom surface f3 that is the bottom P of the groove portion 30C, lateral surfaces f1, ff1 located between the bottom surface f3 and the first edge e1, and lateral surfaces f2, ff2 located between the bottom surface f3 and the second edge e2, and hence has steps. The width wa of the bottom surface f3 is smaller than the width w of the opening of the groove portion 30C. The lateral surfaces f1, ff1, f2, ff2 each may be a flat surface inclined with respect to the second surface 10b. Because the groove portion 30C has the steps, the creepage distance of insulation between the first electrically-conductive layer 21 and the second electrically-conductive layer 22 can be further increased.

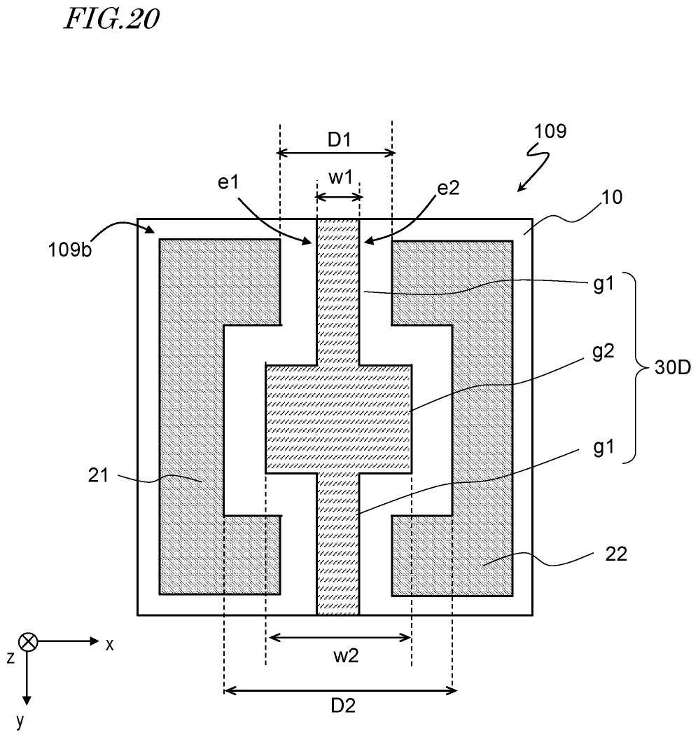

FIG. 20 is a bottom view of an alternative substrate 109 of Variant Example 4. In the substrate 109, in a plan view, the groove portion 30D includes a plurality of portions of different opening widths. Specifically, the groove portion 30D includes portions g1 that have a width w1 and a portion g2 that has a width w2. The width w2 is greater than the width w1. These portions g1, g2 may be in communication with one another. In this case, in a plan view, between the first electrically-conductive layer 21 and the second electrically-conductive layer 22, the distance D1 measured across the portion g1 of the first groove portion 31 may be smaller than the distance D2 measured across the portion g2 of the first groove portion 31.

A substrate for light emitting elements and a light emitting device according to the present disclosure are suitably applicable to various uses including lighting devices, camera flashlights, vehicle headlights, etc. The substrate and the light emitting device are particularly suitably applicable to light sources for flashlights of small-size cameras included in smartphones and the like.

It is to be understood that although certain embodiments of the present invention have been described, various other embodiments and variants may occur to those skilled in the art that are within the scope and spirit of the invention, and such other embodiments and variants are intended to be covered by the following claims.

What is claimed is:

1. A substrate for light emitting elements, comprising:
a resin layer having a sheet shape, a first surface, and a second surface located opposite to the first surface, wherein:
the second surface has one or more groove portions that includes a first groove portion,
the second surface is divided by the first groove portion into a plurality of regions that include the first region and the second region, and
the resin layer comprises a plurality of fiber bundles and a resin;
a first electrically-conductive layer located in the first region of the resin layer; and
a second electrically-conductive layer located in the second region of the resin layer; wherein:
in a cross-sectional view including the first electrically-conductive layer, the first groove portion, and the second electrically-conductive layer:
at least one continuous fiber bundle included in the plurality of fiber bundles includes a portion that is located at a position shallower than a bottom of the first groove portion, and
in a plan view, the at least one continuous fiber bundle extends inside the resin layer across the first region, a portion below the first groove portion, and the second region.

2. The substrate of claim 1, wherein:
the at least one fiber bundle includes two or more fiber bundles stacked in a thickness direction of the resin layer between the first surface and the second surface of the resin layer;
the resin layer includes, in a plan view:
a first portion overlapping the first electrically-conductive layer or the second electrically-conductive layer, and
a second portion overlapping the one or more groove portions; and
a stacking interval of the two or more fiber bundles in the second portion is smaller than a stacking interval of the two or more fiber bundles in the first portion.

3. The substrate of claim 1, wherein:
the resin layer includes, in a plan view:
a first portion overlapping the first electrically-conductive layer or the second electrically-conductive layer, and
a second portion overlapping the one or more groove portions; and
a density of the plurality of fiber bundles in the second portion is higher than a density of the plurality of fiber bundles in the first portion.

4. The substrate of claim 1, wherein:
a surface of the one or more groove portions is defined by only a resin portion of the resin layer.

5. The substrate of claim 1, wherein:
in a plan view:
the first groove portion is annular,
the first region is surrounded by the first groove portion, and
the second region is located opposite to the first region with respect to the first groove portion interposed therebetween.

6. The substrate of claim 5, wherein:
the one or more groove portions further include a second groove portion;
in a plan view, in a part of the second surface of the resin layer that is located opposite to the first region with respect to the first groove portion interposed therebetween, the second groove portion is located between the second region and an outer region positioned outward of the second region; and
the second groove portion includes a portion elongated in the shape of an arc or annulus.

7. The substrate of claim 5, wherein:
the second surface of the resin layer has a rectangular shape having four corners;
in a plan view, the second surface of the resin layer further includes:
a third region, a fourth region and a fifth region, and
an outer region positioned outward of the second region, the third region, the fourth region and the fifth region,
the second region, the third region, the fourth region and the fifth region are each located between the first groove portion and a corresponding one of the four corners;
the substrate further includes a third electrically-conductive layer located in the third region, a fourth electrically-conductive layer located in the fourth region, and a fifth electrically-conductive layer located in the fifth region;
in a plan view, the one or more groove portions further include a second groove portion located between the second region and the outer region, a third groove portion located between the third region and the outer region, a fourth groove portion located between the fourth region and the outer region, and a fifth groove portion located between the fifth region and the outer region; and
in a plan view, the second groove portion, the third groove portion, the fourth groove portion and the fifth groove portion have at least one arc portion that is in contact with the first groove portion.

8. The substrate of claim 1, wherein:
in a plan view, the first groove portion extends linearly between the first region and the second region.

9. The substrate of claim 1, wherein:
the one or more groove portions include a groove portion that has, in a plan view, a first position at a periphery of the second surface, a second position that is positioned inside of the second surface, and a linear portion extending linearly from the first position to the second position.

10. The substrate of claim 1, wherein:
the one or more groove portions include a groove portion that includes a plurality of portions of different widths in a plan view.

11. The substrate of claim 1, wherein:
in a cross-sectional view, the one or more groove portions include a first surface and a second surface that are separated by an angle of about 90°.

12. The substrate of claim 1, wherein:
a cross-sectional shape of the one or more groove portions includes a circular or elliptical arc.

13. The substrate of claim 1, wherein:
a width of an opening of the one or more groove portions is greater than a width of a bottom of the groove portion.

14. The substrate of claim 1, wherein:
in a plan view, the first groove portion is provided so as to intersect with a line segment of shortest distance between the first electrically-conductive layer and the second electrically-conductive layer.

15. The substrate of any claim 1, wherein:
a portion of the at least one fiber bundle overlapping the one or more groove portions in a plan view is bent in a depth direction of the one or more groove portions along the one or more groove portions.

16. A light emitting device, comprising:
the substrate according to claim 1, wherein:
the first electrically-conductive layer is a first lower electrically-conductive layer,
the second electrically-conductive layer is a second lower electrically-conductive layer,
the substrate further comprises a first upper electrically-conductive layer and a second upper electrically-conductive layer on the first surface side of the resin layer, the first upper electrically-conductive layer and the second upper electrically-conductive layer being spaced away from each other, and
the first upper electrically-conductive layer is electrically connected to the first lower electrically-conductive layer, and the second upper electrically-conductive layer is electrically connected to the second lower electrically-conductive layer; and
at least one light emitting element provided on the first surface side of the resin layer; wherein:
the at least one light emitting element includes a first light emitting element; and
the first light emitting element comprises a first electrode electrically connected to the first upper electrically-conductive layer, and a second electrode electrically connected to the second upper electrically-conductive layer.

17. A method of producing a substrate for light emitting elements, comprising:
providing a sheet-like metal plate and a pre-preg, the metal plate having a first surface and one or more raised portions at the first surface, the pre-preg comprising a plurality of fiber bundles and a resin;
binding together the first surface of the metal plate and the pre-preg;
forming a resin layer that includes curing the pre-preg;
forming a resist on the metal plate;
etching away the one or more raised portions of the metal plate; and
removing the resist; wherein:
the etching comprises dividing the metal plate by the one or more groove portions into two or more parts that includes a first region and a second region.

18. The method of claim 17, wherein:
the etching includes forming one or more groove portions corresponding to the one or more raised portions in the resin layer.

19. The method of claim 18, wherein:
the resin layer is formed such that a portion of at least one of the plurality of fiber bundles overlapping the one or more groove portions in a plan view is bent in a depth direction along the one or more groove portions.

20. The method of claim 17, wherein:
the one or more raised portions include a raised portion elongated in a shape of an arc or annulus in a plan view.
